(19) United States
(12) Patent Application Publication
(10) Pub. No.: US 2024/0061474 A1
(43) Pub. Date: Feb. 22, 2024

(54) NEAR-FIELD ELECTROMAGNETIC WAVE ABSORBER

(71) Applicant: Seiji KAGAWA, Koshigaya-shi (JP)

(72) Inventors: Seiji KAGAWA, Koshigaya-shi (JP); Yoichiro KAGAWA, Koshigaya-shi (JP)

(73) Assignee: Seiji KAGAWA, Koshigaya-shi (JP)

(21) Appl. No.: 18/218,665

(22) Filed: Jul. 6, 2023

(30) Foreign Application Priority Data
Aug. 19, 2022 (JP) 2022-131275
Oct. 20, 2022 (JP) 2022-168711

(51) Int. Cl. G06F 1/16; H05K 9/00; B32B 15/08; B32B 15/04; B32B 3/30; B32B 7/03; B32B 15/20

(52) U.S. Cl. CPC G06F 1/1656; H05K 9/0084; B32B 15/08; B32B 15/043; B32B 3/30; B32B 7/03; B32B 15/20; B32B 2307/514

(57) ABSTRACT

A near-field electromagnetic wave absorber comprising at least one plastic film and two linearly-scratched thin metal films, each of the linearly-scratched thin metal films having large numbers of substantially parallel, intermittent, linear scratches with irregular widths and intervals in plural directions, one linearly-scratched thin metal film having a surface resistivity of 150-300Ω/square, and the other linearly-scratched thin metal film having a surface resistivity of 10-50Ω/square.

### FIELD OF THE INVENTION

The present invention relates to a near-field electromagnetic wave absorber having high conductive noise absorbability and radiation noise absorbability in a wide frequency range from less than 1 GHz to high single-digit GHz, capable of being used without being connected to a ground because of substantially no frequencies at which radiation noises are maximized, and suffering only small unevenness of noise absorbability among different production lots.

### BACKGROUND OF THE INVENTION

To prevent malfunctions, etc. due to electromagnetic wave noises leaking from electronic devices in various electronic appliances and communications terminals, various electromagnetic wave absorbers have been put into practical use. In such circumstance, the inventor proposed by Japanese Patent 4685977 a linearly-scratched thin metal film-plastic composite film having decreased anisotropy of electromagnetic wave absorbability, which comprises a plastic film, and a single- or multi-layer thin metal film formed on at least one surface of the plastic film, the thin metal film being provided with large numbers of substantially parallel, intermittent, linear scratches with irregular widths and intervals in plural directions. Japanese Patent 4685977 describes that a combination of two linearly-scratched thin metal film-plastic composite films having different crossing angles of linear scratches can efficiently absorb both electric and magnetic fields, with decreased anisotropy of electromagnetic wave absorbability, when one composite film has a surface resistance of 20-377Ω/square, and the other has a surface resistance of 377-10,000Ω/square. However, Japanese Patent 4685977 does not provide any Example, in which two linearly-scratched thin metal film-plastic composite films having different surface resistivities and thus different degrees of forming linear scratches are combined.

When plural lots of thin metal film-plastic composite films are produced with the same surface resistivity target, and two thin metal film-plastic composite films arbitrarily selected from different lots are laminated to produce a near-field electromagnetic wave absorber, good radiation noise absorbability may not be exhibited in a wide frequency range depending on their combination. This appears to be due to the fact that (a) because thin metal films in the linearly-scratched thin metal film-plastic composite films are extremely thin, and (b) because linear scratches are also extremely small, large unevenness occurs depending on actual production conditions, resulting in large unevenness of product performance among production lots.

Japanese Patent 5203295 discloses an electromagnetic-wave-absorbing film obtained by laminating a magnetic composite film comprising a magnetic thin metal film formed on at least one surface of a plastic film with a nonmagnetic composite film comprising a nonmagnetic thin metal film formed on at least one surface of a plastic film, at least one of the magnetic thin metal film and the nonmagnetic thin metal film being provided with large numbers of substantially parallel, intermittent, linear scratches with irregular widths and intervals in at least one direction, the linear scratches having an average width of 1-100 μm and an average interval of 1-100 μm, 90% or more of the linear scratches having widths in a range of 0.1-1,000 μm. Japanese Patent 5203295 describes that electromagnetic-wave-absorbing films comprising a magnetic thin metal film having a surface resistance of 1-377Ω/square and a nonmagnetic thin metal film having a surface resistance of 377-10,000Ω/square have excellent near-field electromagnetic wave noise absorbability.

However, it has been found that electromagnetic wave noises absorbed in Japanese Patent 5203295 are so-called conductive noises, and that with respect to radiation noises in a wide frequency range from less than 1 GHz to high single-digit GHz, there are frequencies at which they are maximized. Intensive research has revealed that the surface resistance of 1-377Ω/square in the linearly-scratched magnetic composite film and the surface resistance of 377-10,000Ω/square in the linearly-scratched nonmagnetic composite film are not well balanced, it is impossible to prevent the maximization of radiation noises in a wide frequency range. Specifically, in Example 1 of Japanese Patent 5203295, the surface resistance of the linearly-scratched magnetic composite film is 30Ω/square, while the surface resistance of the linearly-scratched nonmagnetic composite film is as too large as 6,000Ω/square. Therefore, a ground (GND) should be connected to prevent the maximized noises from leaking, when this electromagnetic-wave-absorbing film is put into practical use for absorbing near-field noises.

WO 2012/090586 A discloses a near-field electromagnetic wave absorber obtained by adhering pluralities of electromagnetic-wave-absorbing films each comprising a thin metal film formed on one surface of a plastic film, at least one electromagnetic-wave-absorbing film having a thin magnetic metal film, and the thin magnetic metal film of at least one electromagnetic-wave-absorbing film being provided with large numbers of substantially parallel, intermittent, linear scratches with irregular widths and intervals in plural directions. WO 2012/090586 A describes that the linearly-scratched thin metal film of each electromagnetic-wave-absorbing film has a surface resistance in a range of 50-1500Ω/square, and that the near-field electromagnetic wave absorber has excellent conductive noise absorbability in a wide frequency range from less than 1 GHz to high single-digit GHz. It has been found, however, that the near-field electromagnetic wave absorber of WO 2012/090586 A has frequencies at which radiation noises are maximized. Accordingly, when this near-field electromagnetic wave absorber is put into practical use, a ground (GND) should be connected to prevent the leaking of maximized noises, as in Japanese Patent 5203295.

Japanese Patent 5559668 discloses an electromagnetic wave absorber obtained by laminating pluralities of electromagnetic-wave-absorbing films via dielectric bodies in front of a electromagnetic wave reflector,
each electromagnetic-wave-absorbing film comprising a conductive material layer formed on a surface of a plastic film, the conductive material layer having a surface resistance in a range of 100-100012/square,
the surface resistance of the conductive material layer of a foremost electromagnetic-wave-absorbing film being larger than that of the conductive material layer of the next electromagnetic-wave-absorbing film by 100Ω/square or more,
(a) when two electromagnetic-wave-absorbing films are contained, a ratio of the gap between the first and second electromagnetic-wave-absorbing films to the gap between the second electromagnetic-wave-absorbing film and the electromagnetic wave reflector being 100/30-80/70, and (b) when three or more electromagnetic-wave-absorbing films are contained, a ratio of the gap between the first and second electromagnetic-wave-absorbing films to the gap between the second and third electromagnetic-wave-absorbing films being 100/30-80/70,
the conductive material layer of the electromagnetic-wave-absorbing film being provided with large numbers of substantially parallel, intermittent, linear scratches with irregular widths and intervals in plural directions, and
the linear scratches having widths, 90% or more of which are in a range of 0.1-100 μm, and 1-50 μm on average, and intervals in a range of 0.1-200 μm and 1-100 μm on average.

Japanese Patent 5559668 describes that because the surface resistance of the conductive material layer of the foremost electromagnetic-wave-absorbing film is larger than that of the conductive material layer of the next electromagnetic-wave-absorbing film by 100Ω/square or more, extremely higher electromagnetic wave absorbability is obtained with smaller anisotropy than when pluralities of electromagnetic-wave-absorbing films having the same surface resistance are simply laminated. However, because this electromagnetic wave absorber has a structure in which pluralities of electromagnetic-wave-absorbing films are laminated via dielectric bodies in front of the electromagnetic wave reflector (aluminum plate), it is suitable for ETC, FRID, etc., but cannot be used as a near-field electromagnetic wave absorber attached to electronic devices, etc.

### Object of the Invention

Accordingly, an object of the present invention is to provide a near-field electromagnetic wave absorber having high conductive noise absorbability and radiation noise absorbability in a wide frequency range from less than 1 GHz to high single-digit GHz, and having substantially no frequencies at which radiation noises are maximized, making it usable with no ground connected, and suffering only small unevenness in noise absorbability among product lots.

### SUMMARY OF THE INVENTION

As a result of intensive research in view of the above object, the inventor has found that a near-field electromagnetic wave absorber having two thin metal films each provided with large numbers of substantially parallel, intermittent, linear scratches with irregular widths and intervals in plural directions has improved near-field radiation noise absorbability when the surface resistivities of both linearly-scratched thin metal films are changed, and that however, a combination of a linearly-scratched thin metal film having a surface resistivity of 20-377Ω/square and a linearly-scratched thin metal film having a surface resistivity of 377-10,000Ω/square as in Japanese Patent 4685977 fails to sufficiently exhibit high near-field radiation noise absorbability in a wide frequency range from less than 1 GHz to high single-digit GHz. Thus, as a result of intensive research to further increase near-field radiation noise absorbability, the inventor has unexpectedly found that by combining a relatively high surface resistivity of 150-300Ω/square with a relatively low surface resistivity of 10-50Ω/square within a range of less than 377Ω/square, which corresponds to the low surface resistivity in Japanese Patent 4685977, it is possible to stably obtain a near-field electromagnetic wave absorber having high conductive noise absorbability and radiation noise absorbability in a wide frequency range from less than 1 GHz to high single-digit GHz, and having substantially no frequencies at which radiation noises are maximized, making it usable without being connected to a ground, and suffering only small unevenness in noise absorbability among product lots. The present invention has been completed based on such findings.

Thus, the near-field electromagnetic wave absorber of the present invention comprises at least one plastic film and two linearly-scratched thin metal films, each of the linearly-scratched thin metal films having large numbers of substantially parallel, intermittent, linear scratches with irregular widths and intervals in plural directions, one linearly-scratched thin metal film having a surface resistivity of 150-300Ω/square, and the other linearly-scratched thin metal film having a surface resistivity of 10-50Ω/square.

In a preferred embodiment of the present invention, a pair of plastic films each having a linearly-scratched thin metal film on one side are adhered to each other. In this case, both linearly-scratched thin metal films are preferably adhered to each other.

In a further preferred embodiment of the present invention, the linearly-scratched thin metal films are provided on both sides of one plastic film.

The thin metal film in which linear scratches are formed is preferably as thick as 20-100 nm.

The thin metal film is preferably made of aluminum.

Linear scratches formed in the thin metal film are preferably oriented in two directions with a crossing angle of 30-90°.

It is preferable that one of the linearly-scratched thin metal films having a surface resistivity of 150-300Ω/square has a light transmittance of 2.5-3.5%, and the other having a surface resistivity of 10-50Ω/square has a light transmittance of 1-2.2%.

Linear scratches formed in both thin metal films preferably have widths in a range of 0.1-100 μm and 2-50 μm on average, and intervals in a range of 0.1-500 μm and 10-100 μm on average.

### Effects of the Invention

The near-field electromagnetic wave absorber of the present invention having the above constitution has high conductive noise absorbability and radiation noise absorbability in a wide frequency range from less than 1 GHz to high single-digit GHz, and can be used without needing the connection of a ground because of substantially no frequencies at which radiation noises are maximized. Also, because one linearly-scratched thin metal film has a relatively high surface resistivity of 150-300Ω/square, and the other linearly-scratched thin metal film has a relatively low surface resistivity of 10-50Ω/square, it is possible to stably obtain a near-field electromagnetic wave absorber suffering only small noise (radiation noise) absorbability unevenness, even though there is unevenness among the produced linearly-scratched thin metal films. The near-field electromagnetic wave absorber of the present invention having such features can be suitably attached to electronic devices in various electronic appliances and communications terminals such as personal computers, cell phones, smartphones, etc., to suppress electromagnetic wave noises.

### BRIEF DESCRIPTION OF THE DRAWINGS

FIG. 1 is a cross-sectional view showing an electromagnetic-wave-absorbing film having a thin metal film with linear scratches.

FIG. 2 is a partial plan view showing an example of linear scratches formed in a thin metal film.

FIG. 3(a) is a partial plan view showing another example of linear scratches.

FIG. 3(b) is a partial plan view showing a further example of linear scratches.

FIG. 3(c) is a partial plan view showing a still further example of linear scratches.

FIG. 4(a) is a perspective view showing an example of apparatuses for producing an electromagnetic-wave-absorbing film.

FIG. 4(b) is a plan view showing the apparatus of FIG. 4(a).

FIG. 4(c) is a cross-sectional view taken along the line A-A in FIG. 4(b).

FIG. 4(d) is an enlarged partial plan view for explaining the principle of forming linear scratches inclined to the moving direction of the film.

FIG. 4(e) is a partial plan view showing the inclination angles of a pattern roll and a push roll to a film in the apparatus of FIG. 4(a).

FIG. 5 is a partial cross-sectional view showing another example of apparatuses for producing an electromagnetic-wave-absorbing film.

FIG. 6 is a perspective view showing a further example of apparatuses for producing an electromagnetic-wave-absorbing film.

FIG. 7 is a perspective view showing a still further example of apparatuses for producing an electromagnetic-wave-absorbing film.

FIG. 8 is a perspective view showing a still further example of apparatuses for producing an electromagnetic-wave-absorbing film.

FIG. 9(a) is a cross-sectional view showing an example of the near-field electromagnetic wave absorbers of the present invention.

FIG. 9(b) is an exploded cross-sectional view of the near-field electromagnetic wave absorber shown in FIG. 9(a).

FIG. 10 is a cross-sectional view showing another example of the near-field electromagnetic wave absorbers of the present invention.

FIG. 11(a) is a plan view showing a system for evaluating the conductive noise absorbability of a near-field electromagnetic wave absorber.

FIG. 11(b) is a cross-sectional view showing a system for evaluating the conductive noise absorbability of a near-field electromagnetic wave absorber.

FIG. 12 is a graph showing the conductive noise absorption ratio Pₗₒₛₛ/Pᵢₙ of the test piece of Reference Example 1 (Comparative Example 2).

FIG. 13(a) is a photograph showing the cumulative radiation noise of the test piece of Reference Example 1 in a frequency range from 0.03 GHz to 3.5 GHz.

FIG. 13(b) is a photograph showing the cumulative radiation noise of the test piece of Reference Example 1 in a frequency range from 3.5 GHz to 7 GHz.

FIG. 14 is a graph showing the conductive noise absorption ratio Pₗₒₛₛ/Pᵢₙ of the test piece of Example 1.

FIG. 15(a) is a photograph showing the cumulative radiation noise of the test piece of Example 1 in a frequency range from 0.03 GHz to 3.5 GHz.

FIG. 15(b) is a photograph showing the cumulative radiation noise of the test piece of Example 1 in a frequency range from 3.5 GHz to 7 GHz.

FIG. 16 is a photograph showing the conductive noise absorption ratio Pₗₒₛₛ/Pᵢₙ of the test piece of Example 2.

FIG. 17 is a photograph showing the conductive noise absorption ratio Pₗₒₛₛ/Pᵢₙ of the test piece of Example 3.

FIG. 18 is a photograph showing the conductive noise absorption ratio Pₗₒₛₛ/Pᵢₙ of the test piece of Example 4.

FIG. 19 is a graph showing the conductive noise absorption ratio Pₗₒₛₛ/Pᵢₙ of the test piece of Comparative Example 1.

FIG. 20 is a graph showing the conductive noise absorption ratio Pₗₒₛₛ/Pᵢₙ of the test piece of Comparative Example 3.

FIG. 21 is a graph showing the conductive noise absorption ratio Pₗₒₛₛ/Pᵢₙ of the test piece of Comparative Example 4.

FIG. 22 is a graph showing the conductive noise absorption ratio Pₗₒₛₛ/Pᵢₙ of the test piece of Comparative Example 5.

FIG. 23 is a graph showing the conductive noise absorption ratio Pₗₒₛₛ/Pᵢₙ of the test piece of Comparative Example 6.

FIG. 24 is a graph showing the conductive noise absorption ratio Pₗₒₛₛ/Pᵢₙ of the test piece of Comparative Example 7.

FIG. 25 is a graph showing the conductive noise absorption ratio Pₗₒₛₛ/Pᵢₙ of the test piece of Comparative Example 8.

FIG. 26 is a graph showing the conductive noise absorption ratio Pₗₒₛₛ/Pᵢₙ of the test piece of Comparative Example 9.

FIG. 27 is a graph showing the conductive noise absorption ratio Pₗₒₛₛ/Pᵢₙ of the test piece of Comparative Example 10.

FIG. 28(a) is a photograph showing the cumulative radiation noise of Sample 1 of Example 5 in a frequency range from 0.03 GHz to 3.5 GHz.

FIG. 28(b) is a photograph showing the cumulative radiation noise of Sample 1 of Example 5 in a frequency range from 3.5 GHz to 7 GHz

FIG. 29(a) is a photograph showing the cumulative radiation noise of Sample 2 of Example 5 in a frequency range from 0.03 GHz to 3.5 GHz.

FIG. 29(b) is a photograph showing the cumulative radiation noise of Sample 2 of Example 5 in a frequency range from 3.5 GHz to 7 GHz

FIG. 30(a) is a photograph showing the cumulative radiation noise of Sample 3 of Example 5 in a frequency range from 0.03 GHz to 3.5 GHz.

FIG. 30(b) is a photograph showing the cumulative radiation noise of Sample 3 of Example 5 in a frequency range from 3.5 GHz to 7 GHz

FIG. 31(a) is a photograph showing the cumulative radiation noise of Sample 4 of Example 5 in a frequency range from 0.03 GHz to 3.5 GHz.

FIG. 31(b) is a photograph showing the cumulative radiation noise of Sample 4 of Example 5 in a frequency range from 3.5 GHz to 7 GHz

FIG. 32(a) is a photograph showing the cumulative radiation noise of Sample 5 of Example 5 in a frequency range from 0.03 GHz to 3.5 GHz.

FIG. 32(b) is a photograph showing the cumulative radiation noise of Sample 5 of Example 5 in a frequency range from 3.5 GHz to 7 GHz

FIG. 33(a) is a photograph showing the cumulative radiation noise of Sample 6 of Example 5 in a frequency range from 0.03 GHz to 3.5 GHz.

FIG. 33(b) is a photograph showing the cumulative radiation noise of Sample 6 of Example 5 in a frequency range from 3.5 GHz to 7 GHz

FIG. 34(a) is a photograph showing the cumulative radiation noise of Sample 7 of Example 5 in a frequency range from 0.03 GHz to 3.5 GHz.

FIG. 34(b) is a photograph showing the cumulative radiation noise of Sample 7 of Example 5 in a frequency range from 3.5 GHz to 7 GHz

FIG. 35(a) is a photograph showing the cumulative radiation noise of Sample 8 of Example 5 in a frequency range from 0.03 GHz to 3.5 GHz.

FIG. 35(b) is a photograph showing the cumulative radiation noise of Sample 8 of Example 5 in a frequency range from 3.5 GHz to 7 GHz

FIG. 36(a) is a photograph showing the cumulative radiation noise of Sample 9 of Example 5 in a frequency range from 0.03 GHz to 3.5 GHz.

FIG. 36(b) is a photograph showing the cumulative radiation noise of Sample 9 of Example 5 in a frequency range from 3.5 GHz to 7 GHz

FIG. 37(a) is a photograph showing the cumulative radiation noise of Sample 10 of Example 5 in a frequency range from 0.03 GHz to 3.5 GHz.

FIG. 37(b) is a photograph showing the cumulative radiation noise of Sample 10 of Example 5 in a frequency range from 3.5 GHz to 7 GHz

FIG. 38(a) is a photograph showing the cumulative radiation noise of Sample 1 of Comparative Example 11 in a frequency range from 0.03 GHz to 3.5 GHz.

FIG. 38(b) is a photograph showing the cumulative radiation noise of Sample 1 of Comparative Example 11 in a frequency range from 3.5 GHz to 7 GHz

FIG. 39(a) is a photograph showing the cumulative radiation noise of Sample 2 of Comparative Example 11 in a frequency range from 0.03 GHz to 3.5 GHz.

FIG. 39(b) is a photograph showing the cumulative radiation noise of Sample 2 of Comparative Example 11 in a frequency range from 3.5 GHz to 7 GHz

FIG. 40(a) is a photograph showing the cumulative radiation noise of Sample 3 of Comparative Example 11 in a frequency range from 0.03 GHz to 3.5 GHz.

FIG. 40(b) is a photograph showing the cumulative radiation noise of Sample 3 of Comparative Example 11 in a frequency range from 3.5 GHz to 7 GHz

FIG. 41(a) is a photograph showing the cumulative radiation noise of Sample 4 of Comparative Example 11 in a frequency range from 0.03 GHz to 3.5 GHz.

FIG. 41(b) is a photograph showing the cumulative radiation noise of Sample 4 of Comparative Example 11 in a frequency range from 3.5 GHz to 7 GHz

FIG. 42(a) is a photograph showing the cumulative radiation noise of Sample 5 of Comparative Example 11 in a frequency range from 0.03 GHz to 3.5 GHz.

FIG. 42(b) is a photograph showing the cumulative radiation noise of Sample 5 of Comparative Example 11 in a frequency range from 3.5 GHz to 7 GHz

FIG. 43(a) is a photograph showing the cumulative radiation noise of Sample 6 of Comparative Example 11 in a frequency range from 0.03 GHz to 3.5 GHz.

FIG. 43(b) is a photograph showing the cumulative radiation noise of Sample 6 of Comparative Example 11 in a frequency range from 3.5 GHz to 7 GHz

FIG. 44(a) is a photograph showing the cumulative radiation noise of Sample 7 of Comparative Example 11 in a frequency range from 0.03 GHz to 3.5 GHz.

FIG. 44(b) is a photograph showing the cumulative radiation noise of Sample 7 of Comparative Example 11 in a frequency range from 3.5 GHz to 7 GHz

FIG. 45(a) is a photograph showing the cumulative radiation noise of Sample 8 of Comparative Example 11 in a frequency range from 0.03 GHz to 3.5 GHz.

FIG. 45(b) is a photograph showing the cumulative radiation noise of Sample 8 of Comparative Example 11 in a frequency range from 3.5 GHz to 7 GHz

FIG. 46(a) is a photograph showing the cumulative radiation noise of Sample 9 of Comparative Example 11 in a frequency range from 0.03 GHz to 3.5 GHz.

FIG. 46(b) is a photograph showing the cumulative radiation noise of Sample 9 of Comparative Example 11 in a frequency range from 3.5 GHz to 7 GHz

FIG. 47(a) is a photograph showing the cumulative radiation noise of Sample 10 of Comparative Example 11 in a frequency range from 0.03 GHz to 3.5 GHz.

FIG. 47(b) is a photograph showing the cumulative radiation noise of Sample 10 of Comparative Example 11 in a frequency range from 3.5 GHz to 7 GHz

### DESCRIPTION OF THE BEST MODE OF THE INVENTION

The embodiments of the present invention will be explained referring to the attached drawings, and it should be noted that explanation concerning one embodiment is applicable to other embodiments unless otherwise mentioned. Also, the following explanation is not restrictive, and various modifications may be made within the scope of the present invention.

[1] Electromagnetic-Wave-Absorbing Film

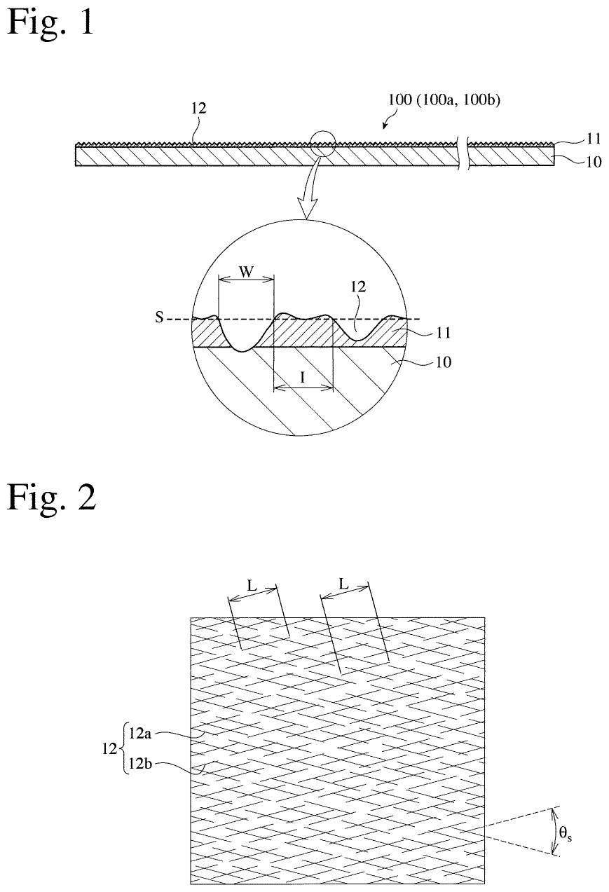

FIG. 1 shows an example of electromagnetic-wave-absorbing films constituting the near-field electromagnetic wave absorber according to one embodiment of the present invention. This electromagnetic-wave-absorbing film 100 (100a, 100b) is constituted by a plastic film 10 and a thin metal film 11 formed on one side of the plastic film 10, and the thin metal film 11 is provided with large numbers of substantially parallel, intermittent, linear scratches 12 with irregular widths and intervals in plural directions.

(1) Plastic Film

Resins foaming the plastic film 10 are not particularly restrictive as long as they have sufficient strength, flexibility and workability in addition to insulation, and they may be, for instance, polyesters (polyethylene terephthalate, etc.), polyarylene sulfide (polyphenylene sulfide, etc.), polyether sulfone, polyetheretherketones, polycarbonates, acrylic resins, polystyrenes, polyolefins (polyethylene, polypropylene, etc.), etc. Among them, a polyethylene terephthalate (PET) film is preferable from the aspect of strength and cost. The thickness of the plastic film 10 may be about 10-100 μm, and preferably about 10-30 μm to make the near-field electromagnetic wave absorber as thin as possible.

(2) Thin Metal Film

The thin metal film 11 is made of a nonmagnetic or magnetic metal. The nonmagnetic metal may be aluminum, copper, silver, etc., and the magnetic metal may be nickel, chromium, etc. Of course, these metals may be used as pure metals or in the forth of alloys. From the aspect of cost and corrosion resistance, aluminum is preferable. The thin metal film 11 can be formed by known methods such as a sputtering method, a vacuum vapor deposition method, etc. From the aspect of controlling the thickness of the thin metal film 11 and the degree of forming linear scratches, the thickness of the thin metal film 11 is preferably 20-100 nm, more preferably 30-90 nm, and most preferably 40-80 nm.

(3) Linear Scratches

As shown in FIGS. 1 and 2, the thin metal film 11 of the electromagnetic-wave-absorbing film 100 (100a, 100b) is provided with substantially parallel, intermittent, linear scratches 12 (12a, 12b) with irregular widths and intervals in plural directions. FIG. 2 shows linear scratches 12a, 12b oriented in two directions. For explanation, the depths of linear scratches 12 are exaggerated in FIG. 1. The linear scratches 12 oriented in two directions have various widths W and intervals I. The intervals I include both of those in parallel to and those in perpendicular to the linear scratches 12. The widths W and intervals I of the linear scratches 12 are measured at an original height of the thin metal film 11, which corresponds to a height of the surface S of the thin metal film 11 before forming linear scratches. Because the linear scratches 12 have various widths W and intervals I, the electromagnetic-wave-absorbing film 100 can efficiently absorb electromagnetic waves in a wide frequency range.

The widths W of the linear scratches 12 are preferably in a range of 0.1-100 μm, more preferably in a range of 0.1-70 μm. The average width Wav of the linear scratches 12 is preferably 2-50 μm, and more preferably 5-30 μm. The intervals I of the linear scratches 12 are preferably in a range of 0.1-500 μm, and more preferably in a range of 1-400 μm. The average interval lay of the linear scratches 12 is preferably 10-100 μm, and more preferably 20-80 μm. Incidentally, to determine the widths W, average width Wav, intervals I and average interval Iav of the linear scratches 12, linear scratches 12 having as small widths as to 0.1 μm are counted unless otherwise mentioned below.

Because the lengths L of the linear scratches 12 are determined by sliding conditions (mainly relative speeds of the roll and the plastic film, and the angle of the plastic film winding around the roll), they are substantially the same unless the sliding conditions are changed (substantially equal to the average length). The lengths of the linear scratches 12 may be practically about 1-100 mm, though not particularly restrictive.

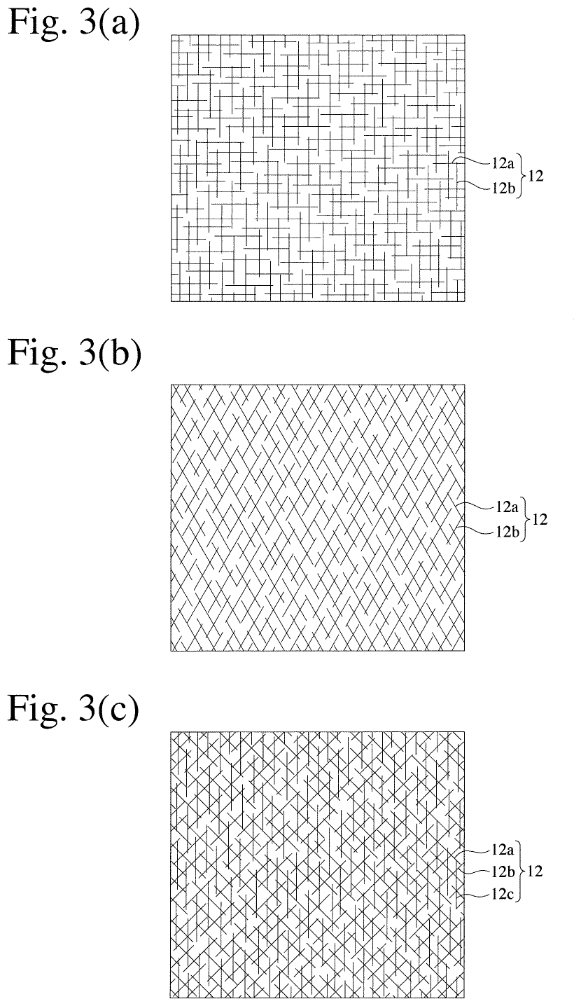

The acute crossing angle θs (hereinafter referred to simply as “crossing angle” unless otherwise mentioned) of the linear scratches 12a, 12b in two directions are preferably 30-90°, more preferably 45-90°, and most preferably 60-90°. With sliding conditions (sliding direction, peripheral speed ratio, etc.) between the plastic film 10 and the pattern roll adjusted, linear scratches 12 with various crossing angles θs can be formed as shown in FIGS. 3(a) to 3(c). Though the orientations of linear scratches are not restricted to two directions but may be three directions or more, the formation of linear scratches in two directions is preferable when production cost and performance are totally taken into consideration. The linear scratches 12 are constituted by perpendicularly crossing linear scratches 12a, 12b in FIG. 3(a), linear scratches 12a, 12b crossing at 60° in FIG. 3(b), and linear scratches 12a, 12b, 12c oriented in three directions in FIG. 3(c).

[2] Apparatus for Forming Linear Scratches

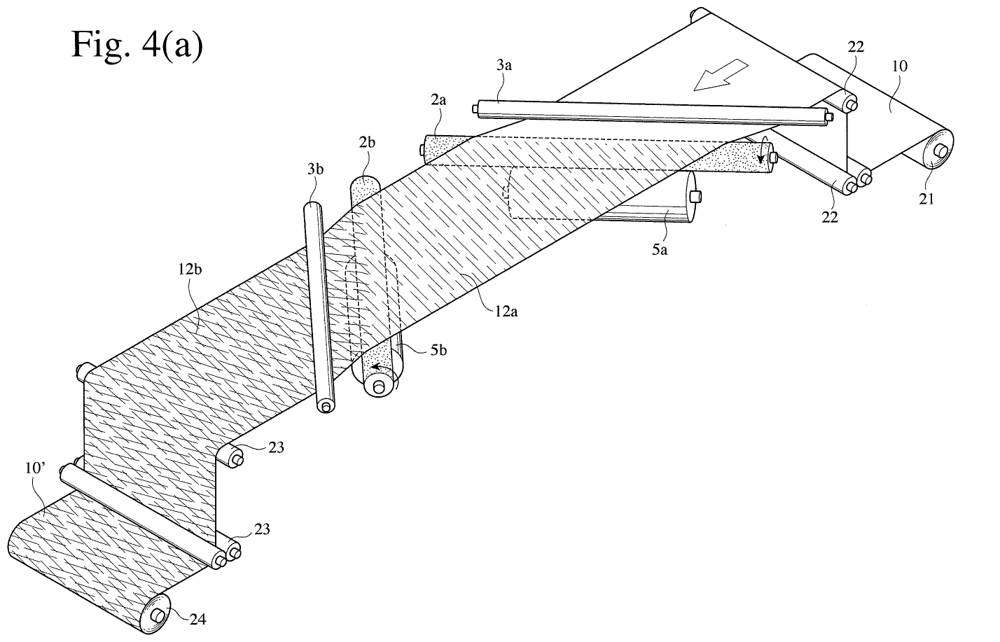

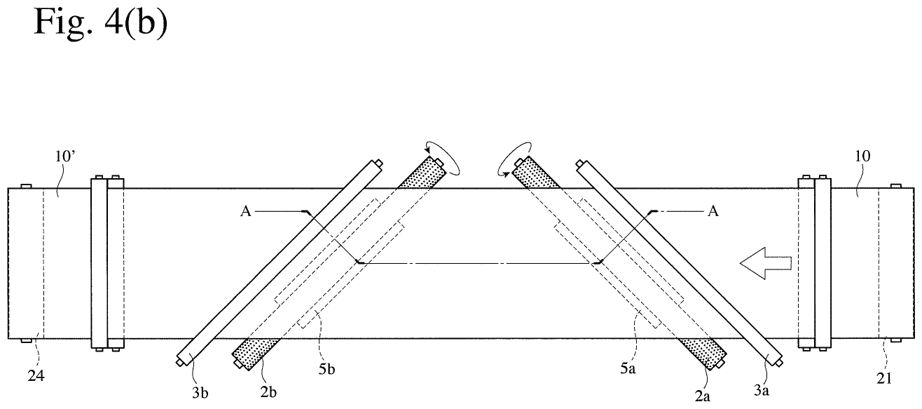

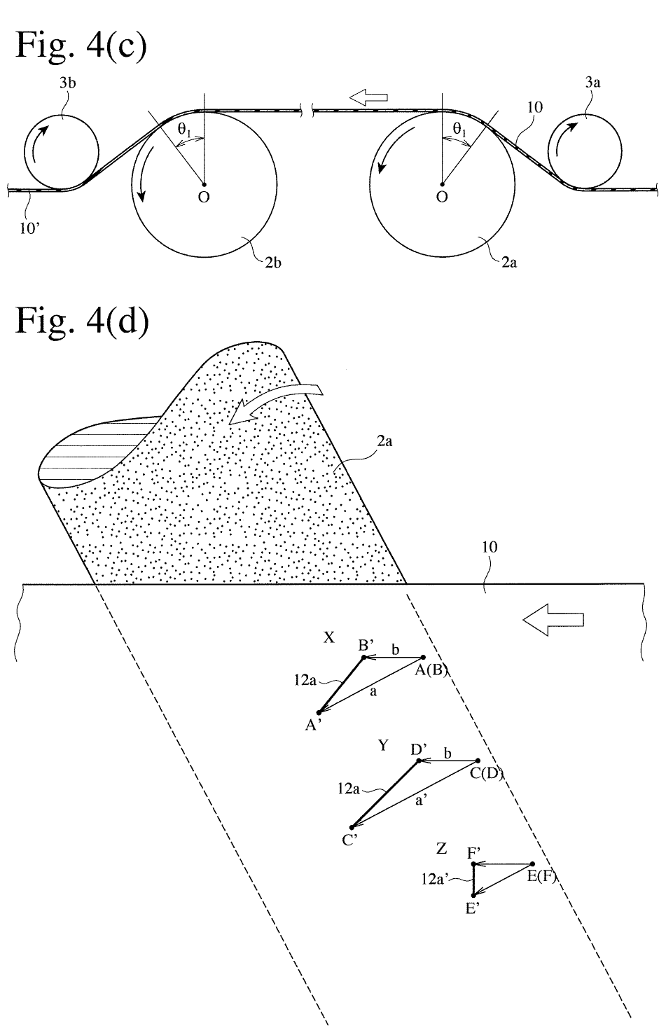

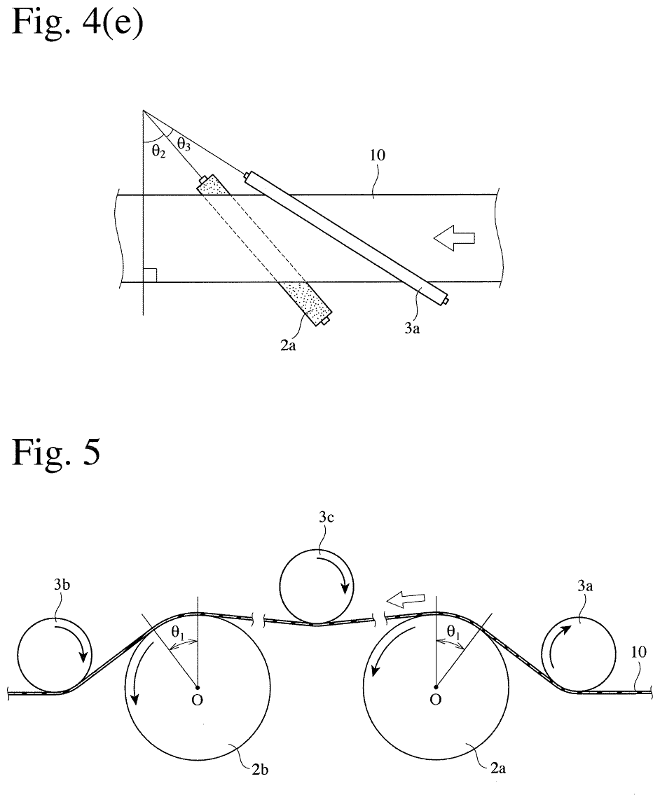

FIGS. 4(a) to 4(e) show one example of apparatuses for forming linear scratches in a thin metal film on a plastic film in two directions. The depicted apparatus comprises (a) a reel 21 from which a plastic film 10 having a thin metal film is wound off, (b) a first pattern roll 2a inclined to the transverse direction of the plastic film 10, (c) a first push roll 3a arranged upstream of the first pattern roll 2a on the opposite side, (d) a second pattern roll 2b inclined to the transverse direction of the plastic film 10 in an opposite direction to the first pattern roll 2a and arranged on the same side as the first pattern roll 2a, (e) a second push roll 3b arranged downstream of the second pattern roll 2b on the opposite side, and (f) a reel 24, around which the plastic film 10′ having a linearly-scratched thin metal film is wound. In addition, pluralities of guide rolls 22, 23 are arranged at predetermined positions. Each pattern roll 2a, 2b is supported by a backup roll (for instance, rubber roll) 5a, 5b to prevent bending.

As shown in FIG. 4(c), because each push roll 3a, 3b comes into contact with the thin metal film of the plastic film 10 at a lower position than the position at which it is brought into sliding contact with each pattern roll 2a, 2b, the plastic film 10 is pushed by each pattern roll 2a, 2b. By adjusting the height of each push roll 3a, 3b with this condition met, the pressing power of each pattern roll 2a, 2b to the thin metal film can be controlled. Specifically, the lower position of each push roll 3a, 3b increases the pressing power of each pattern roll 2a, 2b to the thin metal film of the plastic film 10, forming deeper linear scratches in the thin metal film (increasing the degree of forming linear scratches in the thin metal film). Oppositely, the higher position of each push roll 3a, 3b decreases the pressing power of each pattern roll 2a, 2b to the thin metal film of the plastic film 10, forming shallower linear scratches in the thin metal film of the plastic film 10 (decreasing the degree of forming linear scratches in the thin metal film).

Increase in the depth of linear scratches generally results in a smaller amount of a metal remaining in the thin metal film, providing the linearly-scratched thin metal film with higher surface resistivity. Accordingly, the surface resistivity of the linearly-scratched thin metal film can be adjusted by changing the pressing power of each pattern roll 2a, 2b to the thin metal film of the plastic film 10. Incidentally, deeper linear scratches tend to have larger widths, resulting in smaller intervals between adjacent linear scratches. The pressing power of each pattern roll 2a, 2b to the plastic film 10 can be adjusted by displacing each pattern roll 2a, 2b toward or away from the plastic film 10. The displacement of each pattern roll 2a, 2b can be conducted by a driving mechanism (not shown) attached to each pattern roll 2a, 2b.

FIG. 4(d) shows the principle that linear scratches 12a are formed with inclination to the moving direction of the plastic film 10. Because the pattern roll 2a is inclined to the moving direction of the plastic film 10, the moving direction (rotation direction) of fine, hard particles on the pattern roll 2a differs from the moving direction of the plastic film 10. After a fine, hard particle on a point A on the pattern roll 2a comes into contact with the thin metal film of the plastic film 10 to form a scratch B at an arbitrary time as shown by X, the fine, hard particle moves to a point A′, and the scratch B moves to a point B′, in a predetermined period of time. While the fine, hard particle moves from the point A to the point A′, the scratch is continuously formed, resulting in a linear scratch 12a extending from the point A′ to the point B′.

The directions and crossing angle θs of linear scratches 12a, 12b formed by the first and second pattern rolls 2a, 2b can be adjusted by changing the angle of each pattern roll 2a, 2b to the plastic film 10, and/or the peripheral speed of each pattern roll 2a, 2b relative to the moving speed of the plastic film 10. For instance, when the peripheral speed a of the pattern roll 2a relative to the moving speed b of the plastic film 10 increases, the linear scratches 12a can be inclined 45° to the moving direction of the plastic film 10 like a line C′D′ as shown by Y in FIG. 4(d). Similarly, the peripheral speed a of the pattern roll 2a can be changed by changing the inclination angle θ₂ of the pattern roll 2a to the transverse direction of the plastic film 10 as shown in FIG. 4 (e). This is true of the pattern roll 2b. Accordingly, with both pattern rolls 2a, 2b adjusted, the directions of linear scratches 12a, 12b can be changed.

Because each pattern roll 2a, 2b is inclined to the plastic film 10, sliding with each pattern roll 2a, 2b applies a force in a transverse direction to the plastic film 10. Accordingly, to prevent the lateral movement of the plastic film 10, the height and/or angle of each push roll 3a, 3b to each pattern roll 2a, 2b are preferably adjusted. For instance, as shown in FIG. 4 (e), the proper adjustment of a crossing angle θ₃ between the axis of the pattern roll 2a and the axis of the push roll 3a provides the pressing power with such a transverse distribution as to cancel transverse components, thereby preventing the lateral movement. The adjustment of a distance between the pattern roll 2a and the push roll 3a also contributes to the prevention of the lateral movement. To prevent the lateral movement and breakage of the plastic film 10, the rotation directions of the first and second pattern rolls 2a, 2b inclined to the transverse direction of the plastic film 10 are preferably the same as the moving direction of the plastic film 10.

To increase the pressing power of the pattern rolls 2a, 2b to the thin metal film of the plastic film 10, a third push roll 3c may be provided between the pattern rolls 2a, 2b as shown in FIG. 5. The third push roll 3c increases the sliding distance of the plastic film 10 proportional to the center angle θ₁, resulting in longer linear scratches 12a, 12b. The adjustment of the position and inclination angle of the third push roll 3c contributes to the prevention of the lateral movement of the plastic film 10.

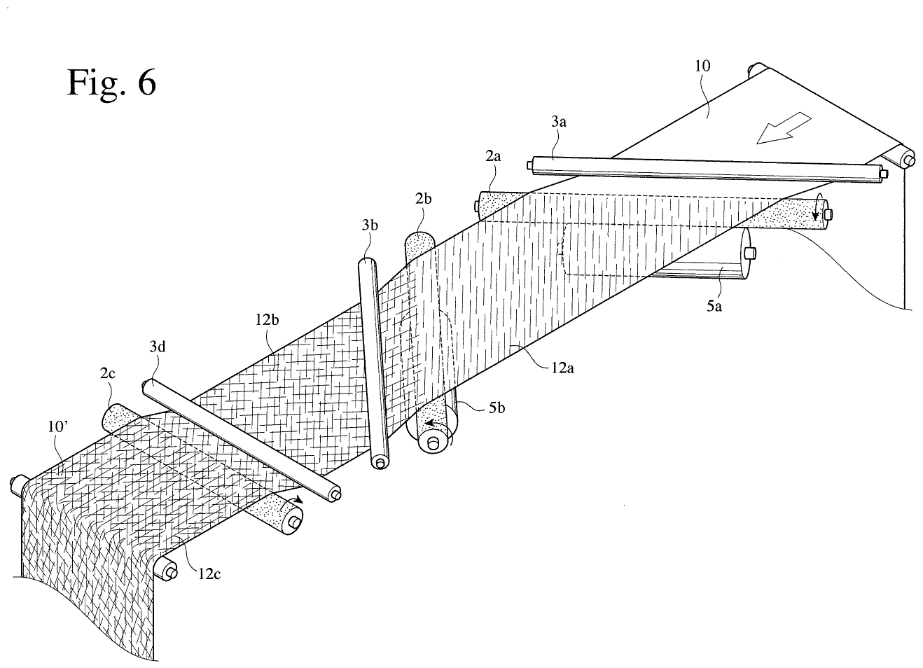

FIG. 6 shows one example of apparatuses for forming linear scratches oriented in three directions as shown in FIG. 3(c). This apparatus is different from the apparatus shown in FIGS. 4(a) to 4(e) in that it comprises a third pattern roll 2c and a third push roll 3d parallel to the transverse direction of the plastic film 10 downstream of the second pattern roll 2b. Though the rotation direction of the third pattern roll 2c may be the same as or opposite to the moving direction of the plastic film 10, it is preferably an opposite direction to form linear scratches efficiently. The third pattern roll 2c parallel to the transverse direction forms linear scratches 12c aligned with the moving direction of the plastic film 10. Though the third push roll 3d is arranged upstream of the third pattern roll 2c, it may be on the downstream side. Not restricted to the depicted examples, the third pattern roll 2c may be arranged upstream of the first pattern roll 2a, or between the first and second pattern rolls 2a, 2b.

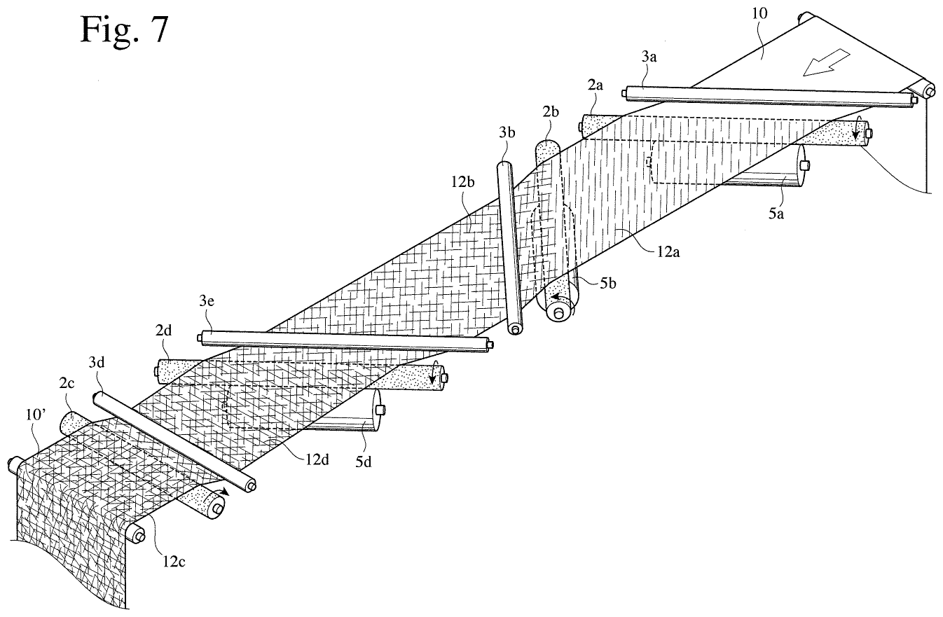

FIG. 7 shows one example of apparatuses for forming linear scratches oriented in four directions. This apparatus is different from the apparatus shown in FIG. 6, in that it comprises a fourth pattern roll 2d between the second pattern roll 2b and the third pattern roll 2c, and a fourth push roll 3e upstream of the fourth pattern roll 2d. With a slower rotation speed of the fourth pattern roll 2d, the direction (line E′F′) of linear scratches 12a′ can be made in parallel to the transverse direction of the plastic film 10 as shown by Z in FIG. 4(d).

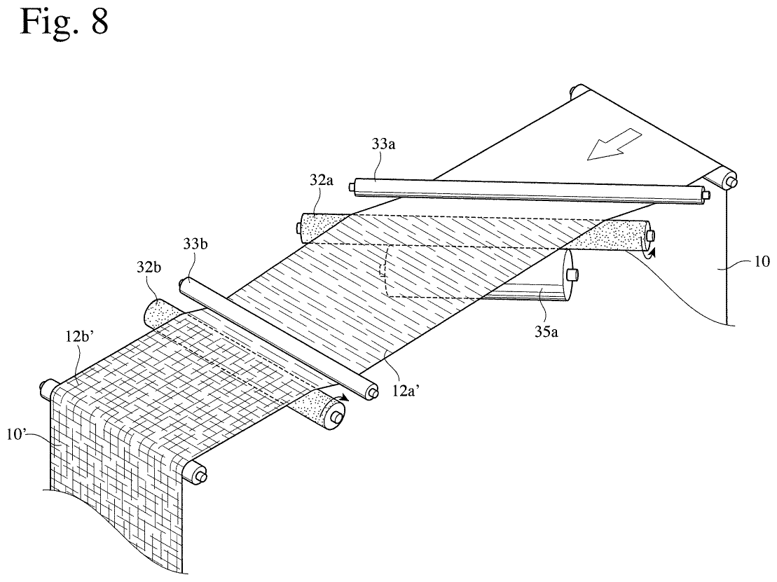

FIG. 8 shows another example of apparatuses for foaming perpendicularly crossing linear scratches as shown in FIG. 3(a). This apparatus is different from the apparatus shown in FIGS. 4(a) to 4(e), in that a second pattern roll 32b is in parallel to the transverse direction (perpendicular to the moving direction) of the plastic film 10. Thus, only portions different from those shown in FIGS. 4(a) to 4(e) will be explained. The rotation direction of the second pattern roll 32b may be the same as or opposite to the moving direction of the plastic film 10. Also, the second push roll 33b may be upstream or downstream of the second pattern roll 32b. This apparatus makes the direction (line E′F′) of linear scratches 12a′ in alignment with the transverse direction of the plastic film 10 as shown by Z in FIG. 4(d), suitable for forming perpendicularly crossing linear scratches.

The moving speed of the plastic film 10 is preferably 5-200 m/minute, and the peripheral speed of the pattern roll is preferably 10-2,000 m/minute. The inclination angles θ₂ of the pattern rolls are preferably 20° to 60°, particularly about 45°. The tension (in parallel to the pressing power) of the plastic film 10 is preferably 0.05-5 kgf/cm width.

The pattern roll is preferably a roll having fine particles with sharp edges and Mohs hardness of 5 or more on the surface, for instance, the diamond roll described in JP 2002-59487 A. Because the widths of linear scratches are determined by the sizes of fine particles, 90% or more of fine diamond particles preferably have sizes in a range of 0.1-100 μm, more preferably in a range of 0.1-70 μm. The fine diamond particles are attached to the roll surface preferably in an area ratio of 30% or more.

[3] Constitution of Near-Field Electromagnetic Wave Absorber

(1) Structure

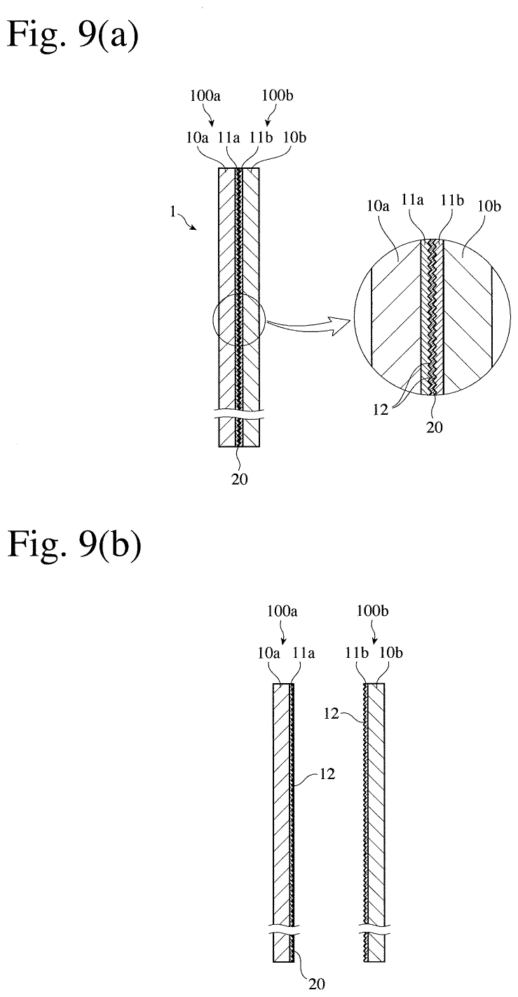

As shown in FIGS. 9(a) and 9(b), the near-field electromagnetic wave absorber according to an embodiment of the present invention is obtained by adhering a first electromagnetic-wave-absorbing film 100a having one (first) thin metal film 11a with linear scratches 12, to a second electromagnetic-wave-absorbing film 100b having the other (second) thin metal film 11b with linear scratches 12. The adhesion is preferably conducted with the linearly-scratched thin metal films 11a, 11b inside, though not restrictive. The near-field electromagnetic wave absorber according to an embodiment of the present invention has a layer structure comprising the first electromagnetic-wave-absorbing film 100a (plastic film 10a/thin metal film 11a with first linear scratches 12), an adhesive layer 20, and the second electromagnetic-wave-absorbing film 100b (thin metal film 11b/plastic film 10b with second linear scratches 12). Because the thin metal films 11a, 11b are facing each other, the adhesive layer 20 is preferably nonconductive to prevent the conduction of the thin metal films 11a, 11 b. The adhesive layer 20 can be formed by applying an adhesive, though it may be formed by heat seal or a two-faced adhesive tape.

This near-field electromagnetic wave absorber can be produced by applying an adhesive 20 to one linearly-scratched thin metal film 11a, and then pressing both electromagnetic-wave-absorbing films 100a, 100b to each other via the adhesive, as shown in FIG. 9(b).

When the adhesive layer 20 is very thin, the thin metal films 11a and 11b are electromagnetically coupled. In this case, it is preferable that linear scratches 12a, 12b formed in the thin metal film 11a and those formed in the thin metal film 11b have different crossing angles θs, to reduce the anisotropy of electromagnetic wave absorbability. The thickness of the adhesive layer 20 is preferably 1-30 μm, and more preferably 1-20 μm.

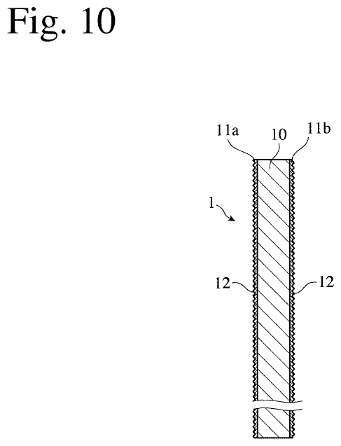

FIG. 10 shows the near-field electromagnetic wave absorber according to another embodiment of the present invention. This near-field electromagnetic wave absorber is constituted by one plastic film 10 and thin metal films 11a, 11b formed on both sides of the plastic film 10, and each thin metal film 11a, 11b is provided with large numbers of substantially parallel, intermittent, linear scratches 12 with irregular widths and intervals in plural directions.

(2) Surface Resistivity of Linearly-Scratched Thin Metal Film

It has been found that though an electromagnetic-wave-absorbing film having a linearly-scratched thin metal film and a near-field electromagnetic wave absorber composed of a laminate of two such electromagnetic-wave-absorbing films generally exhibit good radiation noise absorbability, large radiation noises may leak depending on frequency. Frequencies at which large radiation noises leak cannot be predicted but confirmed only by experiment. As a result of laminating two of the same electromagnetic-wave-absorbing films each having a thin metal film with various degrees of forming linear scratches to form a near-field electromagnetic wave absorber and measuring leaking radiation noises, it has been found that leaking radiation noises differ depending on the degree of forming linear scratches. It has also been found that not only because the thin metal film is extremely thin, but also because the linear scratches are extremely small, there is unevenness in surface resistivity among production lots of near-field electromagnetic wave absorbers, and even products having the same target degree of forming linear scratches suffer unevenness in the leaking level of radiation noises. Intensive research has revealed that (a) when a pair of electromagnetic-wave-absorbing films have linearly-scratched thin metal films with different surface resistivities, and (b) when their surface resistivities are limited in predetermined ranges, radiation noises can be suppressed in a wide frequency range, with small unevenness among production lots. The present invention has been completed based on such findings.

In electronic parts, in general, noises in a range from 0.03 GHz to 7 GHz should be removed. As a result of intensive research on the combination of surface resistivities of the linearly-scratched thin metal films capable of suppressing radiation noises in this range, it has been found that when one linearly-scratched thin metal film has a surface resistivity of 150-300Ω/square, and the other linearly-scratched thin metal film has a surface resistivity of 10-50 Ω/square, radiation noises in a frequency range from 0.03 GHz to 7 GHz can be suppressed, with reduced unevenness among production lots.

As described above, in an electromagnetic-wave-absorbing film having a linearly-scratched thin metal film, and a near-field electromagnetic wave absorber constituted by a laminate of two such electromagnetic-wave-absorbing films, radiation noises may be extremely large (maximized) at one or more frequencies. The maximized radiation noises should be removed at any frequency, and the maximization of radiation noises can be practically confirmed by observing radiation noises cumulated in a predetermined frequency range. When cumulative radiation noise in a predetermined frequency range is less than a desired level, it is regarded that radiation noises are suppressed. On the other hand, when the cumulative radiation noise exceeds the desired level, it is presumed that radiation noises are maximized at a certain frequency. Accordingly, the radiation noise absorbability of the near-field electromagnetic wave absorber is herein evaluated by the level of cumulative radiation noises.

In a frequency range from 0.03 GHz to 7 GHz, the desired level of cumulative radiation noise differs between a low-frequency side and a high-frequency side. Here, the desired level of cumulative radiation noise is −20 dBm in a frequency range from 0.03 GHz to less than 3.5 GHz, and −30 dBm in a frequency range from 3.5 GHz to 7 GHz. Accordingly, when the cumulative radiation noise is −20 dBm or more in a frequency range from 0.03 GHz to less than 3.5 GHz or −30 dBm or more in a frequency range from 3.5 GHz to 7 GHz, it is presumed that radiation noises are maximized at one or more frequencies. If there is a maximized radiation noise at least one frequency, the near-field electromagnetic wave absorber should be connected to a ground to remove the radiation noise.

One (first) linearly-scratched thin metal film 11a has a surface resistivity of 150-300Ω/square, and the other (second) linearly-scratched thin metal film 11b has a surface resistivity of 10-50Ω/square. The first linearly-scratched thin metal film 11a is mainly effective for absorbing conductive noises, and the second linearly-scratched thin metal film 11b is mainly effective for absorbing radiation noises.

When the surface resistivity of the first linearly-scratched thin metal film 11a is less than 150Ω/square, the near-field electromagnetic wave absorber cannot exhibit good conductive noise absorbability. The term “good conductive noise absorbability” used herein means that the near-field electromagnetic wave absorber exhibits a conductive noise absorption ratio Pₗₒₛₛ/Pᵢₙ close to that of the linearly-scratched thin metal film having a surface resistivity of 150-300Ω/square in a frequency range from less than 1 GHz to high single-digit GHz (specifically 0.1-6 GHz). On the other hand, when the surface resistivity of the first linearly-scratched thin metal film 11a is more than 300Ω/square, sufficient radiation noise absorbability cannot be exhibited. To exhibit good conductive noise absorbability and radiation noise absorbability, the surface resistivity of the first linearly-scratched thin metal film 11a is preferably 150-210Ω/square.

When the second linearly-scratched thin metal film 11b has a surface resistivity of less than 10Ω/square, its characteristics are close to those of a thin metal film per se. Namely, it exhibits high radiation noise absorbability with low conductive noise absorbability. Also, when the second linearly-scratched thin metal film 11b has a surface resistivity of more than 50Ω/square, the near-field electromagnetic wave absorber has too low radiation noise absorbability.

Because higher surface resistivity is obtained by deeper and wider linear scratches formed in the thin metal film (higher degree of forming linear scratches) as described above, linear scratches formed in the thin metal film of the second electromagnetic-wave-absorbing film 100b are shallower than those formed in the thin metal film of the first electromagnetic-wave-absorbing film 100a. Accordingly, the second linearly-scratched thin metal film 11b has noise-absorbing characteristics closer to those of an unscratched thin metal film than the first linearly-scratched thin metal film 11a.

Because a larger degree of forming linear scratches in the thin metal film provides the linearly-scratched thin metal film with higher surface resistivity, a desired surface resistivity can be obtained by adjusting the degree of forming linear scratches. Also, because the surface resistivity tends to be lower when the thin metal film becomes thicker even with the same degree of forming linear scratches, the degree of forming linear scratches should be increased for a thicker metal film, to obtain a desired surface resistivity.

The combination of a linearly-scratched thin metal film having a surface resistivity of 150-300Ω/square and a linearly-scratched thin metal film having a surface resistivity of 10-50Ω/square can suppress the maximization of radiation noises in a wide frequency range from less than 1 GHz to high single-digit GHz, while keeping good conductive noise absorbability.

(3) Light Transmittance of Linearly-Scratched Thin Metal Film

The light transmittance of the linearly-scratched thin metal film increases as the degree of forming linear scratches in the thin metal film increases, like the surface resistivity. Specifically, the first linearly-scratched thin metal film 11a having a surface resistivity of 150-300 Ω/square has a light transmittance of 2.5-3.5%, and the second linearly-scratched thin metal film 11b having a surface resistivity of 10-50 Ω/square has a light transmittance of 1-2.2%.

The present invention will be explained in more detail referring to Examples below without intention of restricting it thereto.

### Reference Example 1

A PET film as thick as 16 μm was vapor-deposited with aluminum in vacuum, to form a thin aluminum film as thick as 60 nm. Using an apparatus having the structure shown in FIG. 8 comprising pattern rolls 32a, 32b having electroplated fine diamond particles having a particle size distribution of 50-80 μm, the thin aluminum film on the plastic film was scratched in two directions to form the electromagnetic-wave-absorbing film of Reference Example 1 having linear scratches having the characteristics shown below. The degree of faulting linear scratches in Reference Example 1 was classified in “M₁” (Middles).

| | | |
|---|---|---|
| Range of widths W | 0.1-50 | μm, |
| Average width Wav | 22 | μm, |
| Range of transverse intervals I | 1-120 | μm, |
| Average transverse interval Iav | 42 | μm, |

| | |
|---|---|
| Average length Lav | 5 mm, and |
| Crossing angle θs | 90°. |

Using a sheet resistance/surface resistivity meter “EC-80P” available from Napson Corporation, the surface resistivity of the linear-scratched thin aluminum film was measured by a non-destructive eddy current testing method. The measurement result revealed that the surface resistivity of the linear-scratched thin aluminum film was 172Ω/square.

The electromagnetic-wave-absorbing film of Reference Example 1 having the linear-scratched thin aluminum film was set in a laser thrubeam sensor (IB-30) available from Keyence Corporation, to measure the light transmittance of the linear-scratched thin aluminum film. As a result, the light transmittance was 2.6%.

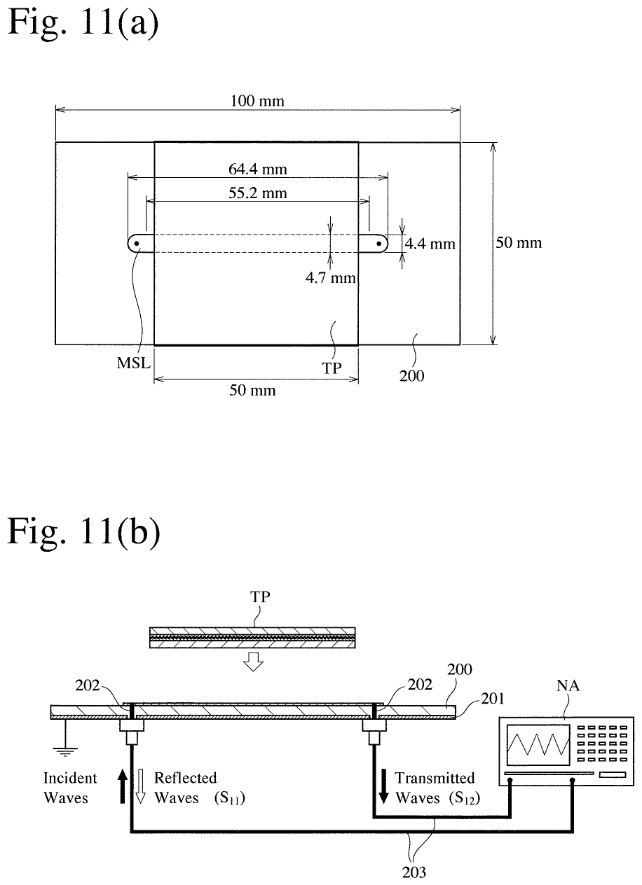

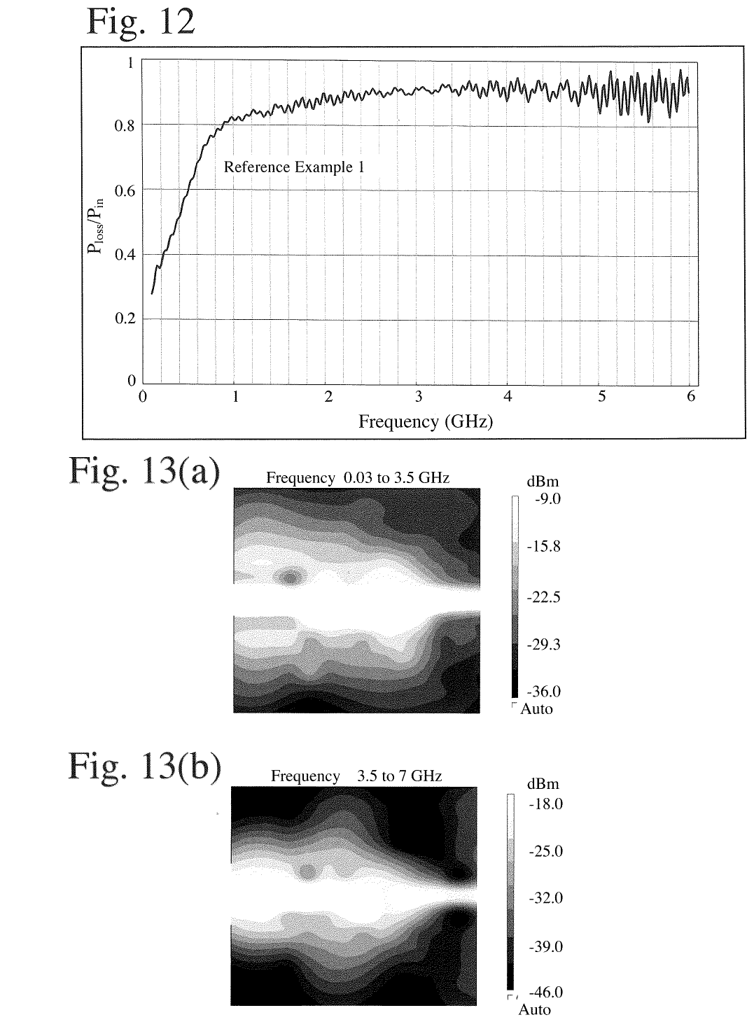

A test piece TP1 (50 mm×50 mm) was cut out of the electromagnetic-wave-absorbing film of Reference Example 1. In a near-field electromagnetic wave evaluation system comprising a microstripline MSL (64.4 mm×4.4 mm) of 50Ω, an insulation substrate 200 supporting the microstripline MSL, a grounded electrode 201 attached to a lower surface of the insulation substrate 200, conductor pins 202, 202 connected to both edges of the microstripline MSL, a network analyzer NA, and coaxial cables 203, 203 for connecting the network analyzer NA to the conductor pins 202, 202 as shown in FIGS. 11(a) and 11(b), the test piece TP1 was attached to an upper surface of the insulation substrate 200 by an adhesive, such that the center of the test piece TP1 was aligned with the center of microstripline MSL. Reflected wave power S₁₁ and transmitted wave power S₁₂ were measured with incident waves of 0.1-6 GHz, to determine a conductive noise absorption ratio Pₗₒₛₛ/Pᵢₙ from S₁₁ and S₂₁. The results are shown in FIG. 12. As is clear from FIG. 12, the electromagnetic-wave-absorbing film of Reference Example 1 exhibited a good conductive noise absorption ratio Pₗₒₛₛ/Pᵢₙ.

A test piece TP2 (40 mm×40 mm) cut out of the electromagnetic-wave-absorbing film of Reference Example 1 was scanned by an EMC noise scanner (WM7400) available from Morita Tech Co. Ltd. in a frequency range from 0.03 GHz to 7 GHz, to measure radiation noises. FIGS. 13(a) and 13(b) show the cumulative radiation noises of the test piece TP2 of Reference Example 1 in frequency ranges from 0.03 GHz to less than 3.5 GHz and from 3.5 GHz to 7 GHz, respectively. As is clear from FIGS. 13(a) and 13(b), as large cumulative radiation noises as −15 dBm or more, particularly −10 dBm or more, were observed in an almost entire area of the test piece TP2 in a frequency range from 0.03 GHz to less than 3.5 GHz, and as large cumulative radiation noises as −25 dBm or more, particularly −20 dBm or more, were observed in an almost entire area of the test piece TP2 in a frequency range from 3.5 GHz to 7 GHz.

### Reference Example 2

The electromagnetic-wave-absorbing film of Reference Example 2 was obtained by forming linear scratches having the characteristics described below in a thin aluminum film in two directions in the same manner as in Reference Example 1, except that the pressing power of the pattern rolls 32a, 32b to the plastic film in the apparatus shown in FIG. 8 was made larger than in Reference Example 1. The degree of forming linear scratches in Reference Example 2 was classified in “M₂” (Middle₂).

| | | |
|---|---|---|
| Range of widths W | 0.1-50 | μm, |
| Average width Wav | 25 | μm, |
| Range of transverse intervals I | 1-150 | μm, |
| Average transverse interval Iav | 45 | μm, |

| | |
|---|---|
| Average length Lav | 5 mm, and |
| Crossing angle θs | 90°. |

The surface resistivity and light transmittance of the linear-scratched thin aluminum film measured by the same methods as in Reference Example 1 were 210Ω/square and 3.2%, respectively.

### Reference Example 3

The electromagnetic-wave-absorbing film of Reference Example 3 was obtained by forming linear scratches having the characteristics described below in a thin aluminum film in two directions in the same manner as in Reference Example 1, except that the pressing power of the pattern rolls 32a, 32b to the plastic film in the apparatus shown in FIG. 8 was made smaller than in Reference Example 1. The degree of forming linear scratches in Reference Example 3 was classified in “W₁” (Weak₁).

| | | |
|---|---|---|
| Range of widths W | 0.1-30 | μm, |
| Average width Wav | 7 | μm, |
| Range of transverse intervals I | 15-300 | μm, |
| Average transverse interval Iav | 71 | μm, |

| | |
|---|---|
| Average length Lav | 5 mm, and |
| Crossing angle θs | 90°. |

The surface resistivity and light transmittance of the linear-scratched thin aluminum film measured by the same methods as in Reference Example 1 were 15Ω/square and 1.9%, respectively.

### Reference Example 4

The electromagnetic-wave-absorbing film of Reference Example 4 was obtained by forming linear scratches having the characteristics described below in a thin aluminum film in two directions in the same manner as in Reference Example 1, except that the pressing power of the pattern rolls 32a, 32b to the plastic film in the apparatus shown in FIG. 8 was made smaller than in Reference Example 1 and larger than in Reference Example 3. The degree of forming linear scratches in Reference Example 4 was classified in “W₂” (Weak₂).

| | | |
|---|---|---|
| Range of widths W | 0.1-50 | μm, |
| Average width Wav | 11 | μm, |
| Range of transverse intervals I | 10-210 | μm, |
| Average transverse interval Iav | 56 | μm, |

| | |
|---|---|
| Average length Lav | 5 mm, and |
| Crossing angle θs | 90°. |

The surface resistivity and light transmittance of the linear-scratched thin aluminum film measured by the same methods as in Reference Example 1 were 27Ω/square and 2.2%, respectively.

### Reference Example 5

The electromagnetic-wave-absorbing film of Reference Example 5 was obtained by forming linear scratches having the characteristics described below in a thin aluminum film in two directions in the same manner as in Reference Example 1, except that the pressing power of the pattern rolls 32a, 32b to the plastic film in the apparatus shown in FIG. 8 was made larger than in Reference Example 1. The degree of forming linear scratches in Reference Example 4 was classified in “S₁” (Strong₁).

| | | |
|---|---|---|
| Range of widths W | 0.2-70 | μm, |
| Average width Wav | 31 | μm, |
| Range of transverse intervals I | 0.5-100 | μm, |
| Average transverse interval Iav | 37 | μm, |

| | |
|---|---|
| Average length Lav | 5 mm, and |
| Crossing angle θs | 90°. |

The surface resistivity and light transmittance of the linear-scratched thin aluminum film measured by the same methods as in Reference Example 1 were 624Ω/square and 3.7%, respectively.

### Reference Example 6

The electromagnetic-wave-absorbing film of Reference Example 6 was obtained by forming linear scratches having the characteristics described below in a thin aluminum film in two directions in the same manner as in Reference Example 1, except that the pressing power of the pattern rolls 32a, 32b to the plastic film in the apparatus shown in FIG. 8 was made larger than in Reference Example 5. The degree of forming linear scratches in Reference Example 6 was classified in “S₂” (Strong₂).

| | | |
|---|---|---|
| Range of widths W | 0.3-100 | μm, |
| Average width Wav | 39 | μm, |
| Range of transverse intervals I | 0.5-80 | μm, |
| Average transverse interval Iav | 30 | μm, |

| | |
|---|---|
| Average length Lav | 5 mm, and |
| Crossing angle θs | 90°. |

The surface resistivity and light transmittance of the linear-scratched thin aluminum film measured by the same methods as in Reference Example 1 were 1290Ω/square and 4.1%, respectively.

With respect to the electromagnetic-wave-absorbing films of Reference Examples 1-6, the sizes of linear scratches and the characteristics of the linear-scratched thin aluminum films are summarized in Table 1 below.

TABLE 1

| | Degree of | | | | | Characteristics | |
|---|---|---|---|---|---|---|---|
| | Forming | Size of Linear Scratches (μm) ⁽²⁾ | | | | Surface | Light |
| | Linear | Width | | Interval | | Resistivity | Transmittance |
| No. | Scratches ⁽¹⁾ | Range | Average | Range | Average | (Ω/square) | (%) |
| Ref. Ex. 1 | M₁ | 0.1-50 | 22 | 1-120 | 42 | 172 | 2.6 |
| Ref. Ex. 2 | M₂ | 0.1-50 | 25 | 1-150 | 45 | 210 | 3.2 |
| Ref. Ex. 3 | W₁ | 0.1-30 | 7 | 15-300 | 71 | 15 | 1.9 |
| Ref. Ex. 4 | W₂ | 0.1-50 | 11 | 10-210 | 56 | 27 | 2.2 |
| Ref. Ex. 5 | S₁ | 0.2-70 | 31 | 0.5-100 | 37 | 624 | 3.7 |
| Ref. Ex. 6 | S₂ | 0.3-100 | 39 | 0.5-80 | 30 | 1290 | 4.1 |

Note:
⁽¹⁾ In the degree of forming linear scratches, W₁ < W₂ < M₁ < M₂ < S₁ < S₂.
⁽²⁾ To determine the width range, average width, interval range and average interval of linear scratches, linear scratches having as small widths as to 0.1 μm were counted.

### Example 1

The electromagnetic-wave-absorbing film of Reference Example 1 was adhered to the electromagnetic-wave-absorbing film of Reference Example 3 with their linear-scratched thin aluminum films inside, via a nonconductive adhesive, to produce a near-field electromagnetic wave absorber shown in FIG. 9(a). The thickness of the adhesive layer was 5 μm.

(1) Measurement of Conductive Noises

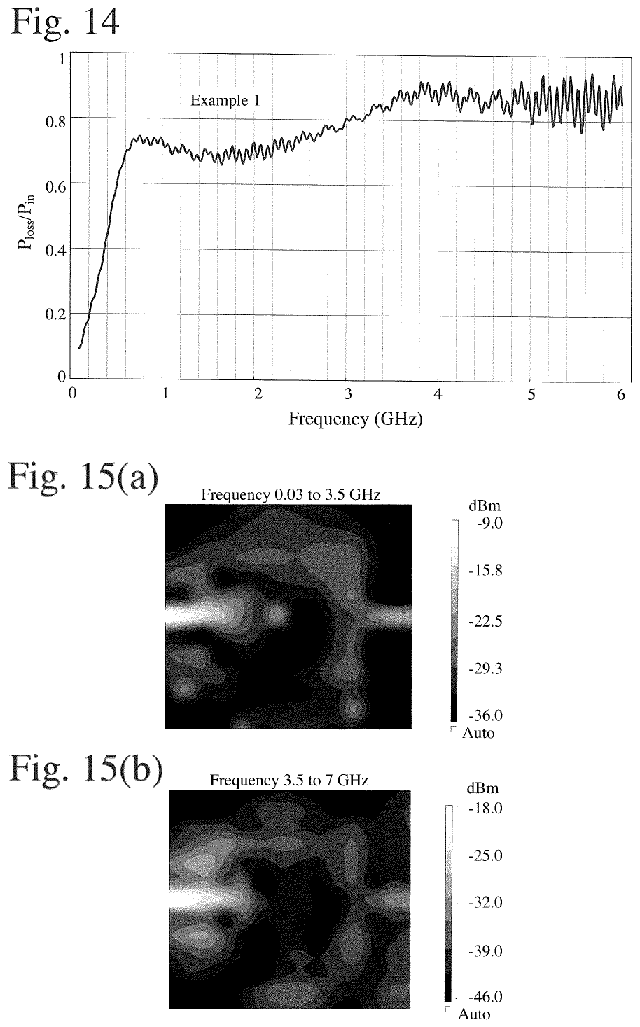

A test piece TP1 (50 mm×50 mm) was cut out of this near-field electromagnetic wave absorber as in Reference Example 1, to measure its conductive noise absorption ratio Pₗₒₛₛ/Pᵢₙ by the near-field electromagnetic wave evaluation system shown in FIGS. 11(a) and 11(b). The results are shown in FIG. 14. As is clear from FIG. 14, the near-field electromagnetic wave absorber of Example 1 exhibited a sufficiently high conductive noise absorption ratio Pₗₒₛₛ/Pᵢₙ, though slightly less than that of the electromagnetic-wave-absorbing film of Reference Example 1.

(2) Measurement of Radiation Noises

A test piece TP2 (40 mm×40 mm) cut out of the near-field electromagnetic wave absorber of Example 1 was scanned by the EMC noise scanner (WM7400) available from Morita Tech Co. Ltd. in a frequency range from 0.03 GHz to 7 GHz, to measure its radiation noises. FIGS. 15(a) and 15(b) show the cumulative radiation noises of the test piece of Example 1 in frequency ranges from 0.03 GHz to less than 3.5 GHz and from 3.5 GHz to 7 GHz, respectively.

As is clear from FIG. 15(a), substantially no cumulative radiation noises of −20 dBm or more were observed in a frequency range from 0.03 GHz to less than 3.5 GHz. Also, as is clear from FIG. 15(b), substantially no cumulative radiation noises of −30 dBm or more were observed in a frequency range from 3.5 GHz to 7 GHz. This confirms that the near-field electromagnetic wave absorber of Example 1 had excellent radiation noise absorbability in a frequency range from 0.03 GHz to 7 GHz.

### Example 2

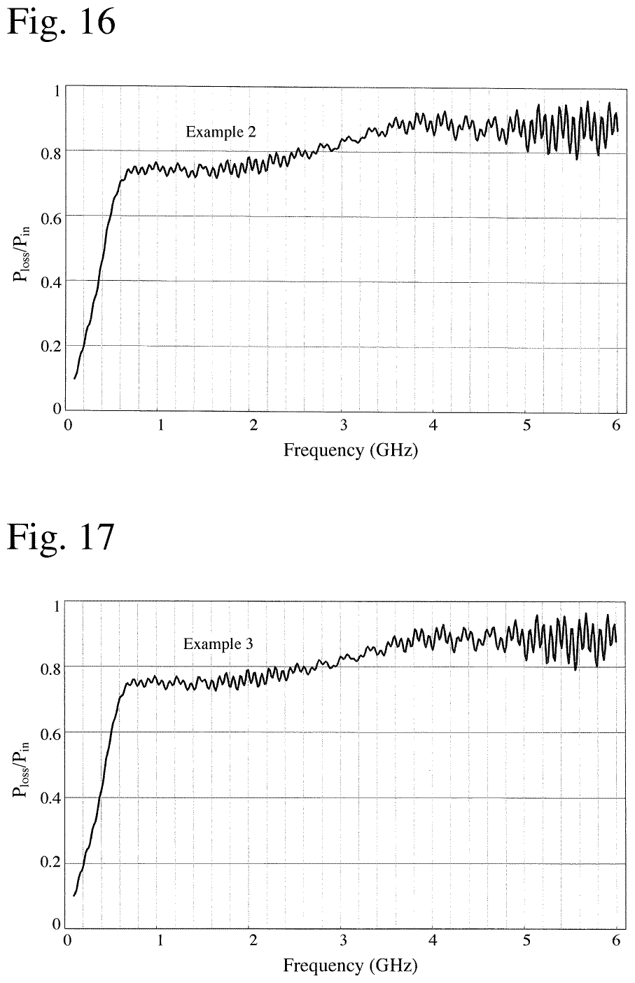

The electromagnetic-wave-absorbing film of Reference Example 1 was adhered to the electromagnetic-wave-absorbing film of Reference Example 4 in the same manner as in Example 1, to produce a near-field electromagnetic wave absorber. Test pieces TP1 and TP2 were cut out of this near-field electromagnetic wave absorber, and measured with respect to a conductive noise absorption ratio Pₗₒₛₛ/Pᵢₙ and radiation noises by the same methods as in Example 1. The results are shown in FIG. 16 and Table 2, respectively. As is clear from FIG. 16, the near-field electromagnetic wave absorber of Example 2 exhibited a sufficiently high conductive noise absorption ratio Pₗₒₛₛ/Pᵢₙ, though slightly lower than that of the electromagnetic-wave-absorbing film of Reference Example 1. Also, the cumulative radiation noises of −20 dBm or more were not observed in a frequency range from 0.03 GHz to less than 3.5 GHz, and the cumulative radiation noises of −30 dBm or more were not observed in a frequency range from 3.5 GHz to 7 GHz.

### Example 3

The electromagnetic-wave-absorbing film of Reference Example 2 was adhered to the electromagnetic-wave-absorbing film of Reference Example 3 in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 17 and Table 2, respectively. As is clear from FIG. 17, the near-field electromagnetic wave absorber of Example 3 exhibited a sufficiently high conductive noise absorption ratio Pₗₒₛₛ/Pᵢₙ, though slightly lower than that of the electromagnetic-wave-absorbing film of Reference Example 1. Also, the cumulative radiation noises of −20 dBm or more were not observed in a frequency range from 0.03 GHz to less than 3.5 GHz, and the cumulative radiation noises of −30 dBm or more were not observed in a frequency range from 3.5 GHz to 7 GHz.

### Example 4

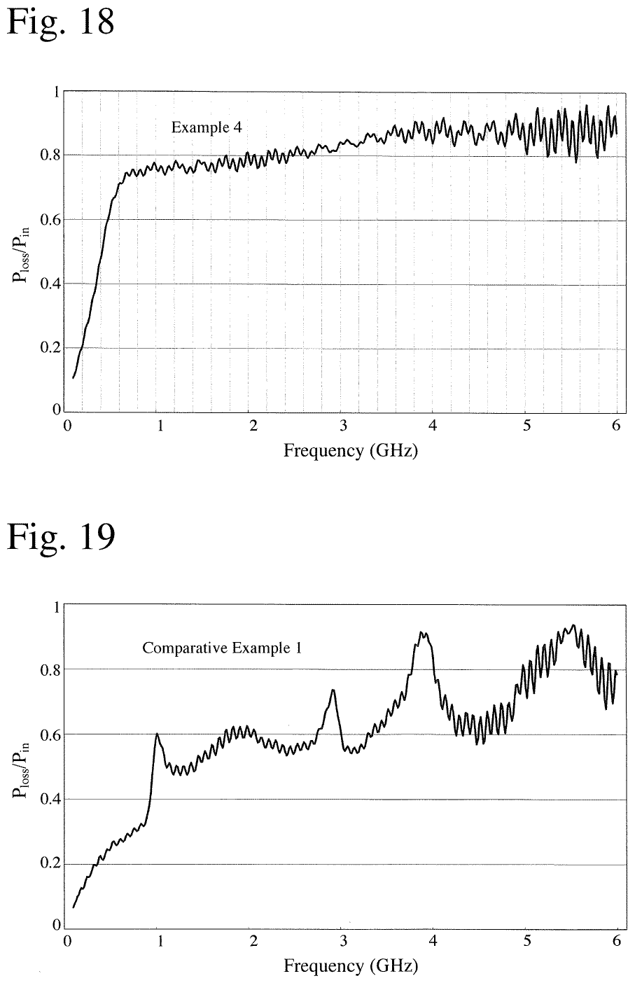

The electromagnetic-wave-absorbing film of Reference Example 2 was adhered to the electromagnetic-wave-absorbing film of Reference Example 4 in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 18 and Table 2, respectively. As is clear from FIG. 18, the near-field electromagnetic wave absorber of Example 4 exhibited a sufficiently high conductive noise absorption ratio Pₗₒₛₛ/Pᵢₙ, though slightly lower than that of the electromagnetic-wave-absorbing film of Reference Example 1. Also, the cumulative radiation noises of −20 dBm or more were not observed in a frequency range from 0.03 GHz to less than 3.5 GHz, and the cumulative radiation noises of −30 dBm or more were not observed in a frequency range from 3.5 GHz to 7 GHz.

### Comparative Example 1

Test pieces TP1 and TP2 composed of only a PET film having a thin aluminum film having a thickness of 60 nm, which was obtained in Reference Example 1, were measured with respect to a conductive noise absorption ratio Pₗₒₛₛ/P and radiation noises by the same methods as in Example 1. The results are shown in FIG. 19 and Table 2, respectively. As is clear from FIG. 19, the test piece TP1 of Comparative Example 1 exhibited an extremely lower conductive noise absorption ratio Pₗₒₛₛ/Pᵢₙ than that of the electromagnetic-wave-absorbing film of Reference Example 1. Also, as large cumulative radiation noises as −15 dBm or more, particularly −10 dBm or more, were observed in an almost entire area of the test piece TP2 in a frequency range from 0.03 GHz to less than 3.5 GHz, and as large cumulative radiation noises as −25 dBm or more, particularly −20 dBm or more, were observed in an almost entire area of the test piece TP2 in a frequency range from 3.5 GHz to 7 GHz. This confirms that the test piece TP2 of Comparative Example 1 extremely leaked radiation noises in a frequency range from 0.03 GHz to 7 GHz.

### Comparative Example 2

Test pieces TP1 and TP2 composed of only the electromagnetic-wave-absorbing film of Reference Example 1 were measured with respect to a conductive noise absorption ratio Pₗₒₛₛ/Pᵢₙ and radiation noises by the same methods as in Example 1. The results are shown in FIG. 12 and Table 2, respectively. Incidentally, the conductive noise absorption ratio Pₗₒₛₛ/Pᵢₙ of Comparative Example 2 was the same as in Reference Example 1 (FIG. 12). Also, as in Comparative Example 1, as large cumulative radiation noises as −15 dBm or more, particularly −10 dBm or more, were observed in an almost entire area of the test piece TP2 in a frequency range from 0.03 GHz to less than 3.5 GHz, and as large cumulative radiation noises as −25 dBm or more, particularly −20 dBm or more, were observed in an almost entire area of the test piece TP2 in a frequency range from 3.5 GHz to 7 GHz. This confirms that the test piece TP2 of Comparative Example 1 extremely leaked radiation noises in a frequency range from 0.03 GHz to 7 GHz.

### Comparative Example 3

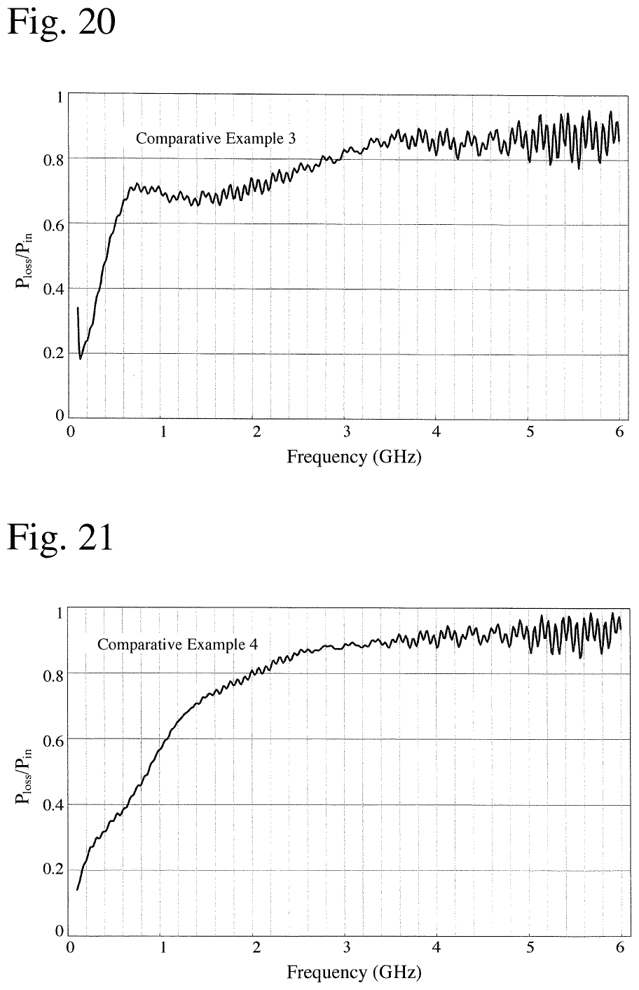

Test pieces TP1 and TP2 composed of only the electromagnetic-wave-absorbing film of Reference Example 3 were measured with respect to a conductive noise absorption ratio Pₗₒₛₛ/Pᵢₙ and radiation noises by the same methods as in Example 1. The results are shown in FIGS. 20 and Table 2, respectively. As is clear from FIG. 20, the test piece TP1 of Comparative Example 3 exhibited a slightly lower conductive noise absorption ratio Pₗₒₛₛ/Pᵢₙ than that of the electromagnetic-wave-absorbing film of Reference Example 1. In a frequency range from 0.03 GHz to less than 3.5 GHz, the cumulative radiation noises of −15 dBm or more were observed only in part of the test piece TP2, but the cumulative radiation noise of −20 dBm to −15 dBm were observed in an almost entire area of the test piece TP2. In a frequency range from 3.5 GHz to 7 GHz, the cumulative radiation noises of −25 dBm or more were observed only in part of the test piece TP2, but the cumulative radiation noises of −30 dBm to −25 dBm were observed in an almost entire area of the test piece TP2. This confirms that the test piece TP2 of Comparative Example 3 leaked large radiation noises in a frequency range from 0.03 GHz to 7 GHz.

### Comparative Example 4

Test pieces TP1 and TP2 composed of only the electromagnetic-wave-absorbing film of Reference Example 5 were measured with respect to a conductive noise absorption ratio Pₗₒₛₛ/Pᵢₙ and radiation noises by the same methods as in Example 1. The results are shown in FIGS. 21 and Table 2, respectively. As is clear from FIG. 21, the test piece TP1 of Comparative Example 4 exhibited a conductive noise absorption ratio Pₗₒₛₛ/Pᵢₙ comparable to that of the electromagnetic-wave-absorbing film of Reference Example 1. However, as large cumulative radiation noises as −15 dBm or more, particularly −10 dBm or more, were observed in an almost entire area of the test piece TP2 in a frequency range from 0.03 GHz to less than 3.5 GHz, and as large cumulative radiation noises as −25 dBm or more, particularly −20 dBm or more, were observed in an almost entire area of the test piece TP2 in a frequency range from 3.5 GHz to 7 GHz. This confirms that the test piece TP2 of Comparative Example 4 leaked extremely large radiation noises in a frequency range from 0.03 GHz to 7 GHz.

### Comparative Example 5

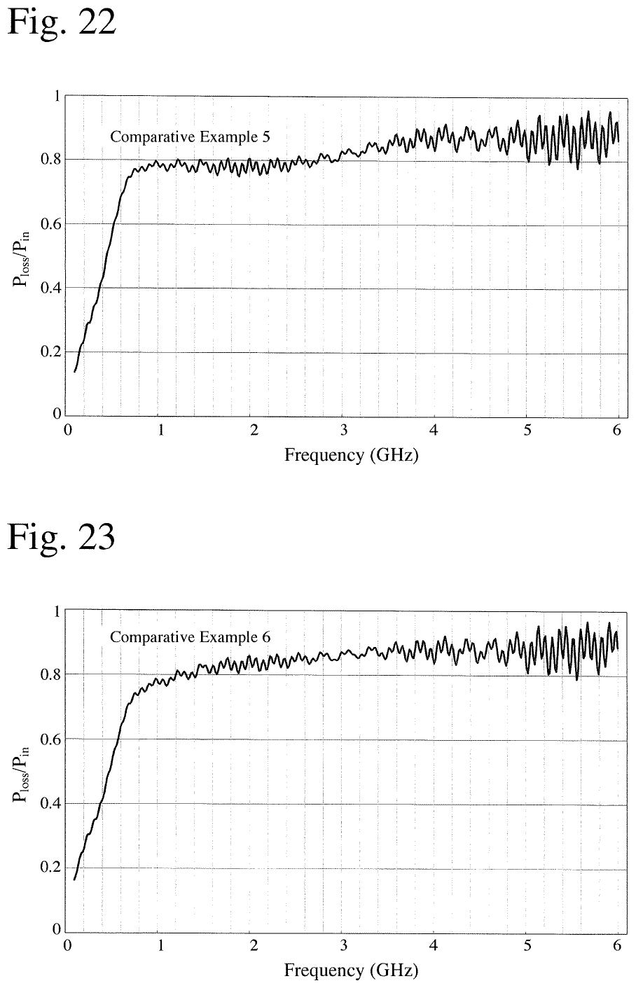

Two electromagnetic-wave-absorbing films of Reference Example 1 were adhered with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 22 and Table 2, respectively. As is clear from FIG. 22, the test piece TP1 of Comparative Example 5 exhibited a conductive noise absorption ratio Pₗₒₛₛ/Pᵢₙ comparable to that of the electromagnetic-wave-absorbing film of Reference Example 1. However, in a frequency range from 0.03 GHz to less than 3.5 GHz, the cumulative radiation noises of −20 dBm to −15 dBm were observed in an almost entire area of the test piece TP2, though the cumulative radiation noises of −15 dBm or more were observed only in part of the test piece TP2. Also, in a frequency range from 3.5 GHz to 7 GHz, the cumulative radiation noises of from −30 dBm to −25 dBm were observed in an almost entire area of the test piece TP2, though the cumulative radiation noises of 25 dBm or more were observed only in part of the test piece TP2. This confirms that the test piece TP2 of Comparative Example 5 leaked large radiation noises in a frequency range from 0.03 GHz to 7 GHz. This appears to be due to the fact that two electromagnetic-wave-absorbing films constituting the near-field electromagnetic wave absorber of Comparative of Example 5 are insufficient in radiation noise absorbability (electromagnetic shielding).

### Comparative Example 6

The electromagnetic-wave-absorbing film of Reference Example 1 was adhered to the electromagnetic-wave-absorbing film of Reference Example with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 23 and Table 2, respectively. As is clear from FIG. 23, the test piece TP1 of Comparative Example 6 exhibited a conductive noise absorption ratio Pₗₒₛₛ/Pᵢₙ comparable to that of the electromagnetic-wave-absorbing film of Reference Example 1. However, in a frequency range from 0.03 GHz to less than 3.5 GHz, the cumulative radiation noises of −20 dBm to −15 dBm were observed in almost half of the test piece TP2, though the cumulative radiation noises of −15 dBm or more were observed only in part of the test piece TP2. Also, in a frequency range from 3.5 GHz to 7 GHz, the cumulative radiation noises of from −30 dBm to −25 dBm were observed in about 20% of the test piece TP2, though the cumulative radiation noises of 25 dBm or more were observed only in part of the test piece TP2. This confirms that the test piece TP2 of Comparative Example 6 leaked large radiation noises in a frequency range from 0.03 GHz to 7 GHz. This appears to be due to the fact that any of the electromagnetic-wave-absorbing films of Reference Examples 1 and 5 constituting the near-field electromagnetic wave absorber of Comparative Example 6 was insufficient in radiation noise absorbability (electromagnetic shielding).

### Comparative Example 7

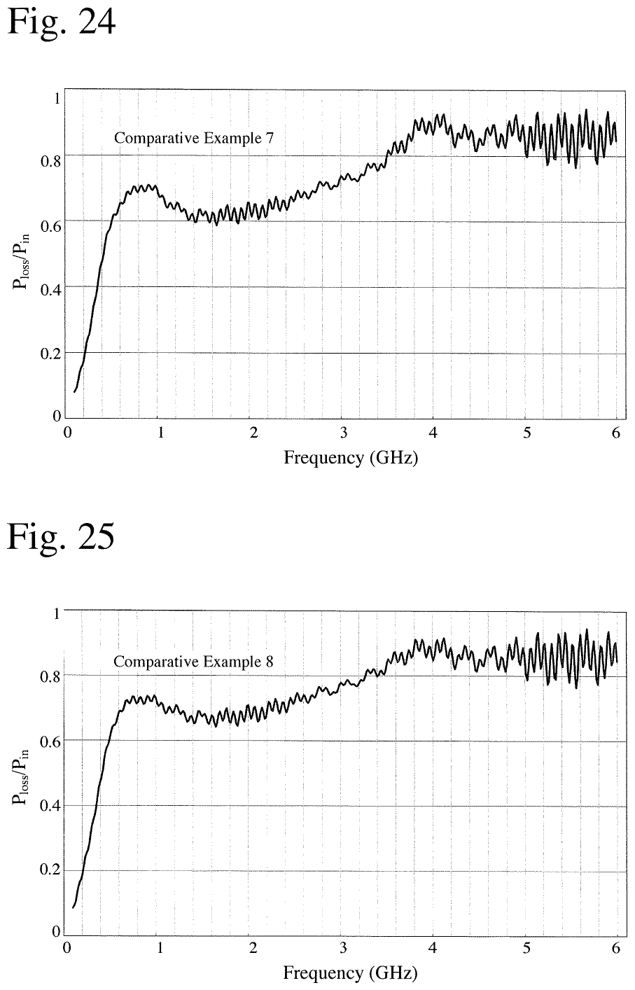

Two electromagnetic-wave-absorbing films of Reference Example 3 were adhered with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 24 and Table 2, respectively. As is clear from FIG. 24, the test piece TP1 of Comparative Example 7 exhibited a lower conductive noise absorption ratio Pₗₒₛₛ/Pᵢₙ than that of the electromagnetic-wave-absorbing film of Reference Example 1. Also, in a frequency range from 3.5 GHz to 7 GHz, the cumulative radiation noises of −25 dBm or more were observed in part of the test piece TP2, and the cumulative radiation noises of −30 dBm to −25 dBm were observed in about 15% of the test piece TP2, though the cumulative radiation noises of −20 dBm or more were not observed in a frequency range from 0.03 GHz to less than 3.5 GHz. This confirms that the test piece TP2 of Comparative Example 7 leaked large radiation noises in a frequency range from 0.03 GHz to 7 GHz. This appears to be due to the fact that two electromagnetic-wave-absorbing films of Reference Example 3 constituting the near-field electromagnetic wave absorber of Comparative Example 7 were insufficient in radiation noise absorbability.

### Comparative Example 8

Two electromagnetic-wave-absorbing films of Reference Example 4 were adhered with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIGS. 25 and Table 2, respectively. As is clear from FIG. 25, the test piece TP1 of Comparative Example 8 exhibited a slightly lower conductive noise absorption ratio Pₗₒₛₛ/Pᵢₙ than that of the electromagnetic-wave-absorbing film of Reference Example 1. Also, in a frequency range from 0.03 GHz to less than 3.5 GHz, the cumulative radiation noises of −20 dBm to −15 dBm were observed in an almost entire area of the test piece TP2, though the cumulative radiation noises of −15 dBm or more were observed only in part of the test piece TP2. Also, in a frequency range from 3.5 GHz to 7 GHz, the cumulative radiation noises of −30 dBm to −25 dBm were observed in almost half of the test piece TP2, though the cumulative radiation noise of −25 dBm or more were observed only in part of the test piece TP2. This confirms that the test piece TP2 of Comparative Example 8 leaked large radiation noises in a frequency range from 0.03 GHz to 7 GHz.

### Comparative Example 9

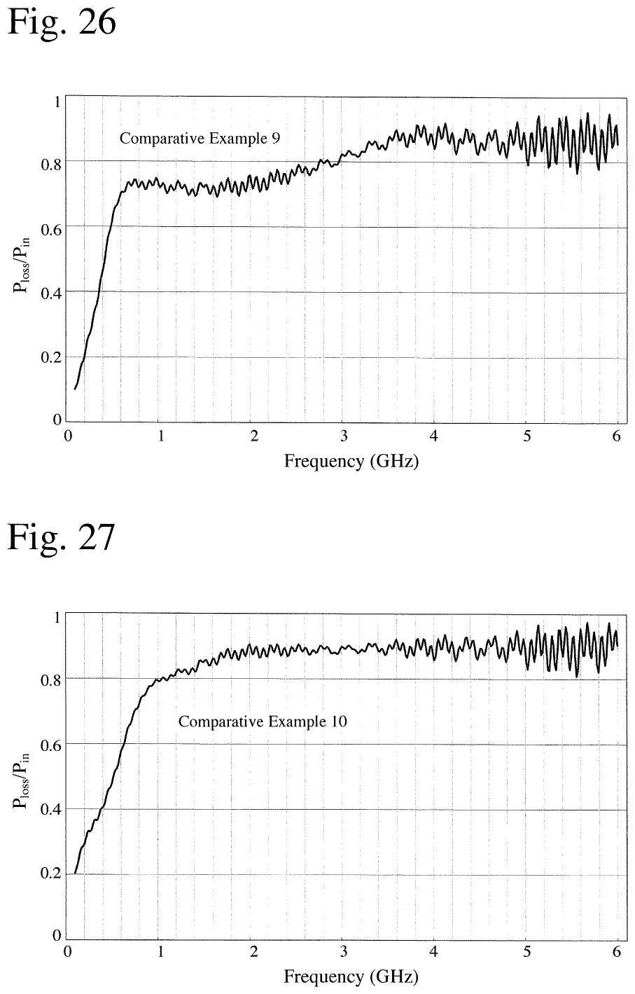

The electromagnetic-wave-absorbing film of Reference Example 3 was adhered to the electromagnetic-wave-absorbing film of Reference Example with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noises by the same methods as in Example 1. The results are shown in FIG. 26 and Table 2, respectively. As is clear from FIG. 26, the test piece TP1 of Comparative Example 9 exhibited a slightly lower conductive noise absorption ratio Pₗₒₛₛ/Pᵢₙ than that of the electromagnetic-wave-absorbing film of Reference Example 1. Also, in a frequency range from 0.03 GHz to less than 3.5 GHz, the cumulative radiation noises of −20 dBm to −15 dBm were observed in about 20% of the test piece TP2, though the cumulative radiation noises of −15 dBm or more were observed only in part of the test piece TP2. Also, in a frequency range from 3.5 GHz to 7 GHz, the cumulative radiation noises of from −30 dBm to −25 dBm were observed in about 10% of the test piece TP2, though the cumulative radiation noises of 25 dBm or more were observed only in part of the test piece TP2. This confirms that the test piece TP2 of Comparative Example 9 leaked large radiation noises in a frequency range from 0.03 GHz to 7 GHz.

### Comparative Example 10

Two electromagnetic-wave-absorbing films of Reference Example 5 were adhered with their linear-scratched thin aluminum films inside in the same manner as in Example 1, to produce a near-field electromagnetic wave absorber. Test pieces TP1 and TP2 were cut out of this near-field electromagnetic wave absorber, to measure a conductive noise absorption ratio Pₗₒₛₛ/Pᵢₙ and radiation noise by the same methods as in Example 1. The results are shown in FIG. 27 and Table 2, respectively. As is clear from FIG. 27, the test piece TP1 of Comparative Example 10 exhibited a conductive noise absorption ratio Pₗₒₛₛ/Pᵢₙ comparable to that of the electromagnetic-wave-absorbing film of Reference Example 1. However, in a frequency range from 0.03 GHz to less than 3.5 GHz, the cumulative radiation noises of −20 dBm to −15 dBm were observed in about 30% of the test piece TP2, though the cumulative radiation noises of −15 dBm or more were observed only in part of the test piece TP2. Also, in a frequency range from 3.5 GHz to 7 GHz, the cumulative radiation noises of from −30 dBm to −25 dBm were observed in about 20% of the test piece TP2, though the cumulative radiation noises of −25 dBm or more were observed only in part of the test piece TP2. This confirms that the test piece TP2 of Comparative Example 10 leaked large radiation noises in a frequency range from 0.03 GHz to 7 GHz.

The results in Comparative Examples 5, 7, 8 and 10 indicate that even though a near-field electromagnetic wave absorber is constituted by two electromagnetic-wave-absorbing films, a well-balanced combination of conductive noise absorbability and radiation noise absorbability would not be obtained if both electromagnetic-wave-absorbing films had the same surface resistivity. Also, the results in Comparative Examples 6 and 9 indicate that even though a near-field electromagnetic wave absorber is constituted by two electromagnetic-wave-absorbing films having different surface resistivities, a well-balanced combination of conductive noise absorbability and radiation noise absorbability would not be obtained if their surface resistivities do not meet the requirements of the present invention.

The constitutions of the near-field electromagnetic wave absorbers of Examples 1-4 and Comparative Examples 1-10, and their conductive noise absorption ratios Pₗₒₛₛ/Pᵢₙ and radiation noises are summarized in Table 2 below.

TABLE 2

| | Combination of | | | |
|---|---|---|---|---|
| | Electromagnetic-Wave-Absorbing Films | | | Cumulative |
| No. | (Degree of Forming Linear Scratches) | | Pₗₒₛₛ/Pᵢₙ | Radiation Noise |
| Example 1 | Ref. Ex. 1 | Ref. Ex. 3 | FIG. 14 | Non |
| | (M₁) | (W₁) | | |
| Example 2 | Ref. Ex. 1 | Ref. Ex. 4 | FIG. 16 | Non |
| | (M₁) | (W₂) | | |
| Example 3 | Ref. Ex. 2 | Ref. Ex. 3 | FIG. 17 | Non |
| | (M₂) | (W₁) | | |
| Example 4 | Ref. Ex. 2 | Ref. Ex. 4 | FIG. 18 | Non |
| | (M₂) | (W₂) | | |
| Comp. Ex. 1 | Only Unscratched Thin Aluminum Film | | FIG. 19 | Extremely Large |
| Comp. Ex. 2 | Only Ref. Ex. 1 (M₁) | | FIG. 12 | Extremely Large |
| Comp. Ex. 3 | Only Ref. Ex. 3 (W₁) | | FIG. 20 | Large |
| Comp. Ex. 4 | Only Ref. Ex. 5 (S₁) | | FIG. 21 | Extremely Large |
| Comp. Ex. 5 | Ref. Ex. 1 | Ref. Ex. 1 | FIG. 22 | Large |
| | (M₁) | (M₁) | | |
| Comp. Ex. 6 | Ref. Ex. 1 | Ref. Ex. 5 | FIG. 23 | Large |
| | (M₁) | (S₁) | | |
| Comp. Ex. 7 | Ref. Ex. 3 | Ref. Ex. 3 | FIG. 24 | Large |
| | (W₁) | (W₁) | | |
| Comp. Ex. 8 | Ref. Ex. 4 | Ref. Ex. 4 | FIG. 25 | Large |
| | (W₂) | (W₂) | | |
| Comp. Ex. 9 | Ref. Ex. 3 | Ref. Ex. 5 | FIG. 26 | Large |
| | (W₁) | (S₁) | | |
| Comp. Ex. 10 | Ref. Ex. 5 | Ref. Ex. 5 | FIG. 27 | Large |
| | (S₁) | (S₁) | | |

### Example 5

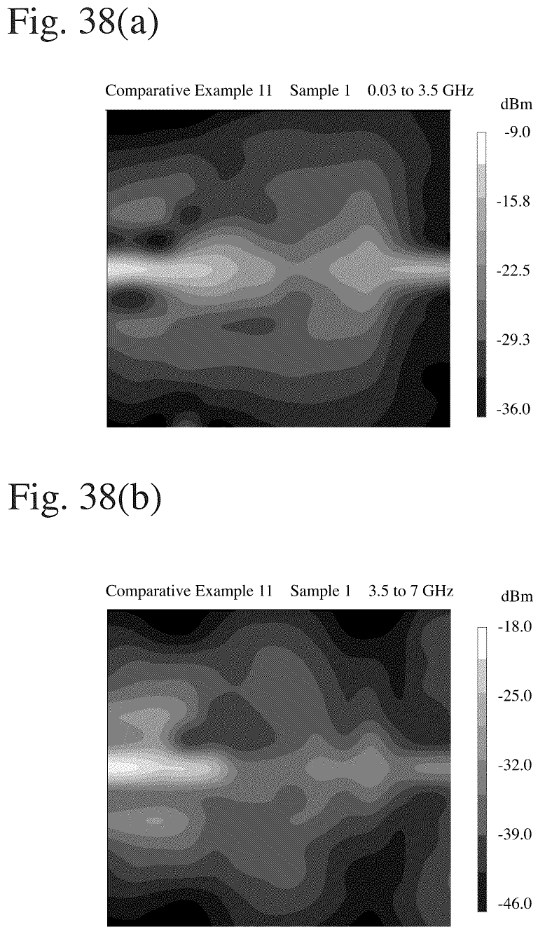

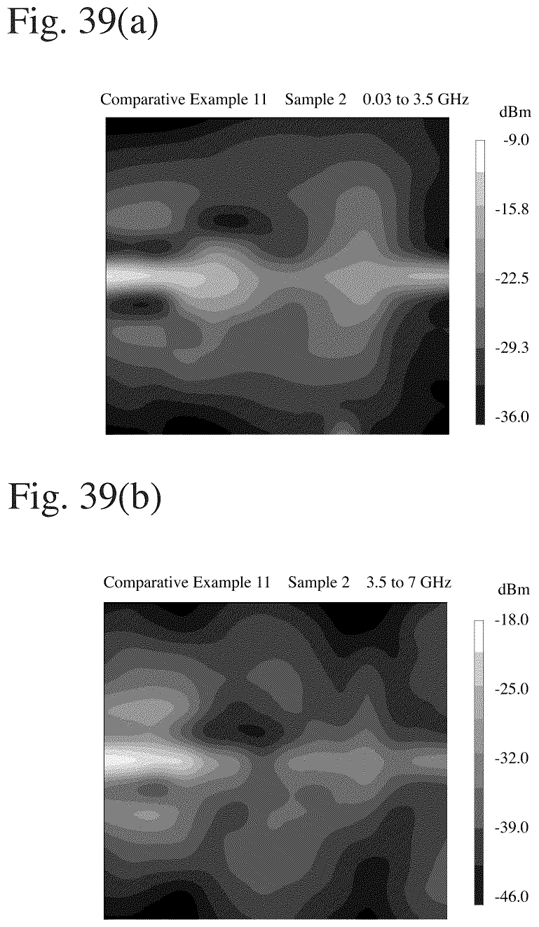

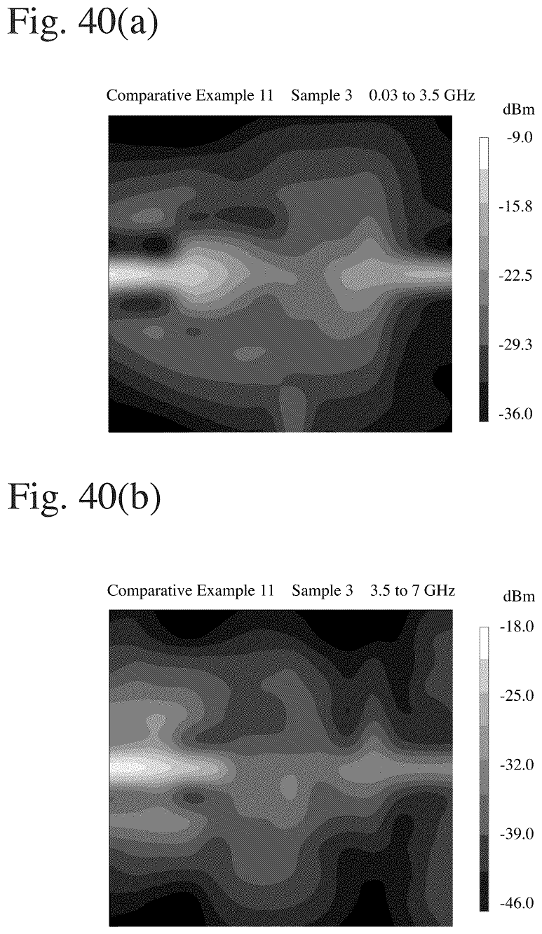

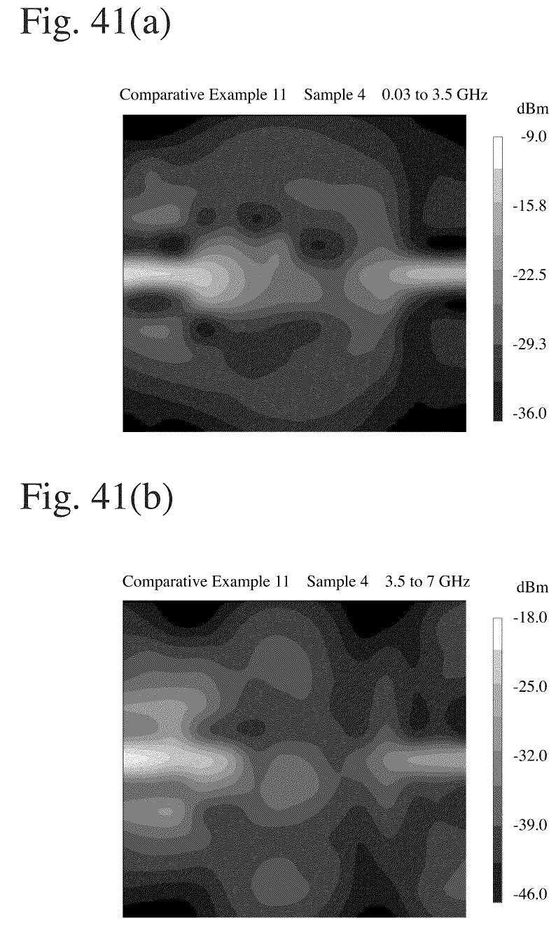

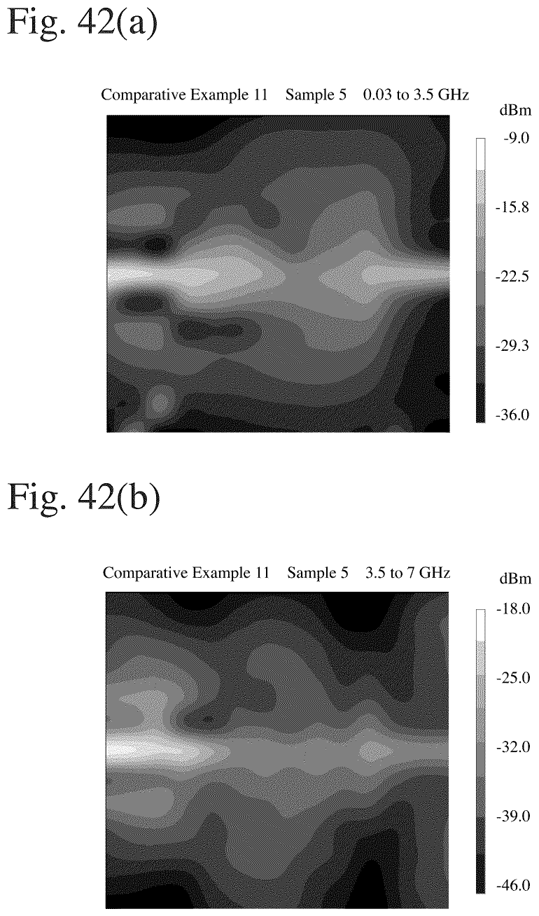

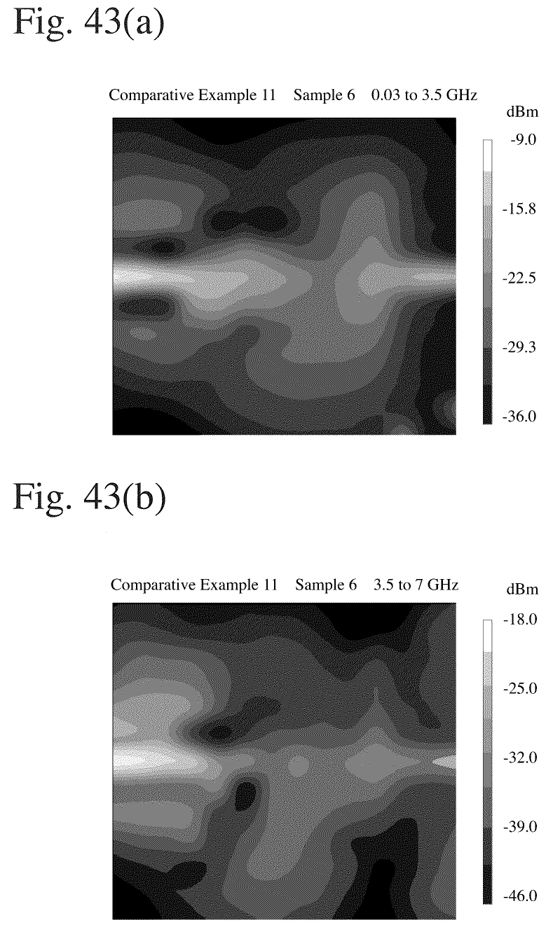

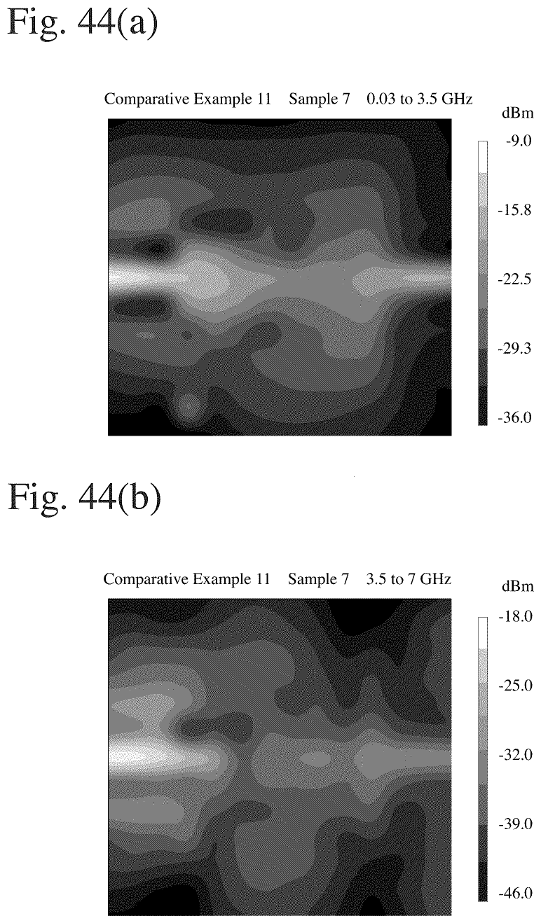

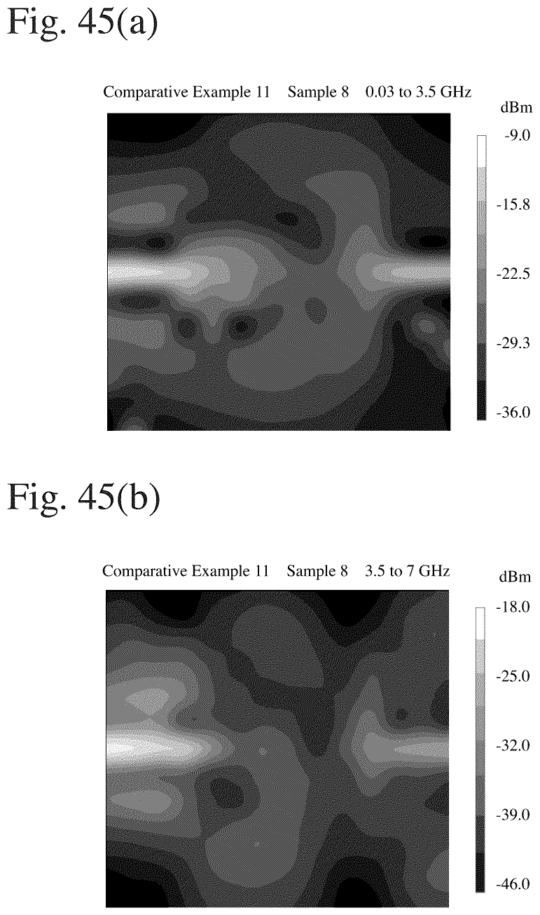

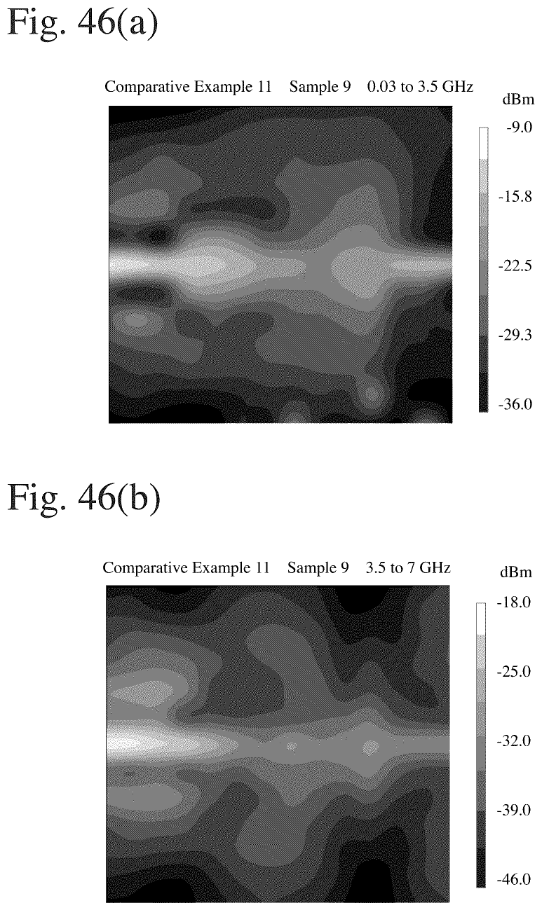

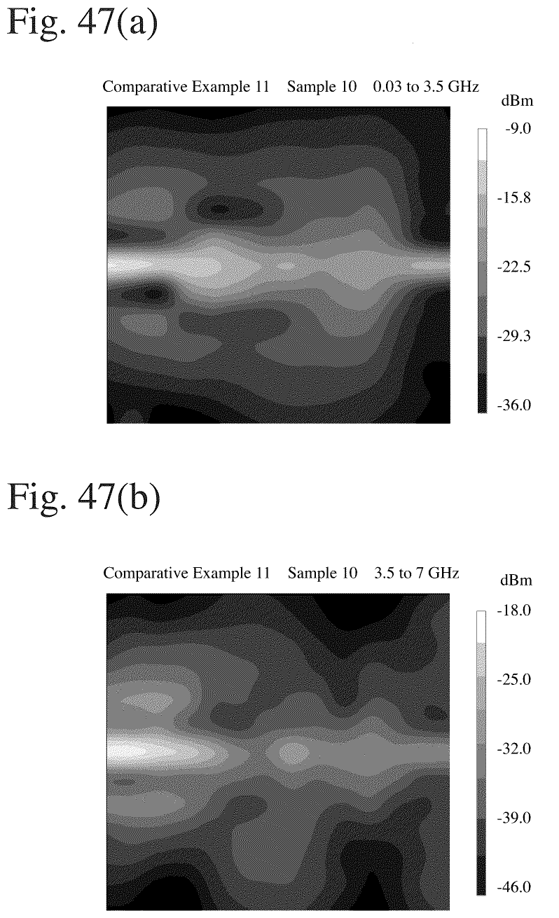

10 electromagnetic-wave-absorbing film pieces A were arbitrarily cut out of a production lot (single roll) of the electromagnetic-wave-absorbing film produced in the same manner as in Reference Example 1, whose degree of forming linear scratches was M₁. Also, 10 electromagnetic-wave-absorbing film pieces B were arbitrarily cut out of a production lot (single roll) of the electromagnetic-wave-absorbing film produced in the same manner as in Reference Example 3, whose degree of forming linear scratches was W₁. Each electromagnetic-wave-absorbing film piece A was arbitrarily combined with each electromagnetic-wave-absorbing film piece B, and adhered by a nonconductive adhesive with their linear-scratched thin aluminum films inside, to obtain 10 near-field electromagnetic wave absorber test pieces TP2. Each of the test pieces TP2 was scanned by the EMC noise scanner (WM7400) available from Morita Tech Co. Ltd. in a frequency range from 0.03 GHz to 7 GHz, to measure radiation noises as in Reference Example 1. FIGS. 38 to 47 show cumulative radiation noises in ranges from 0.03 GHz to 3.5 GHz and from 3.5 GHz to 7 GHz, respectively.

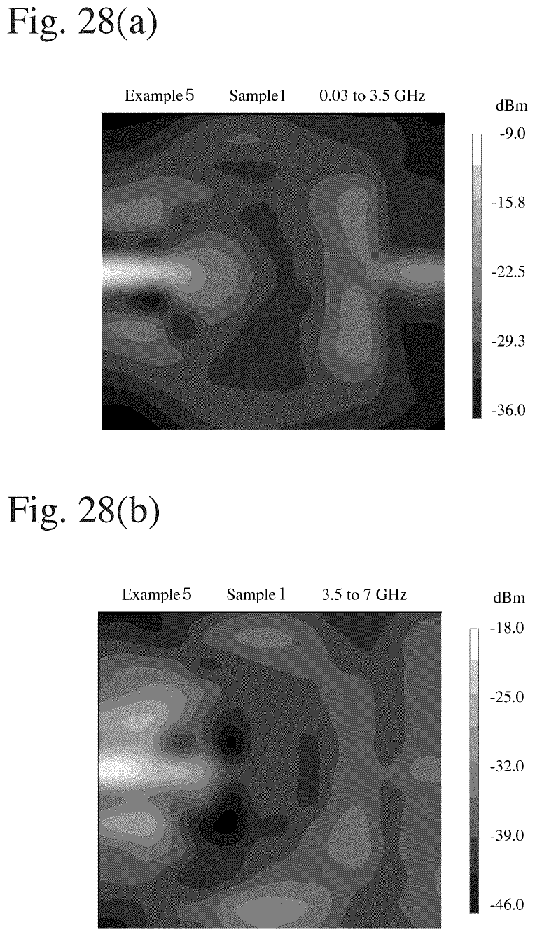

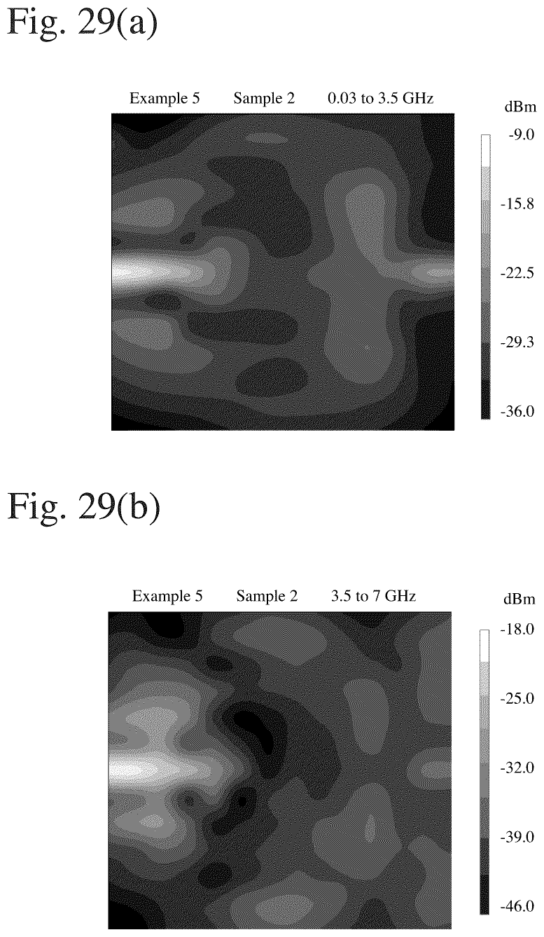

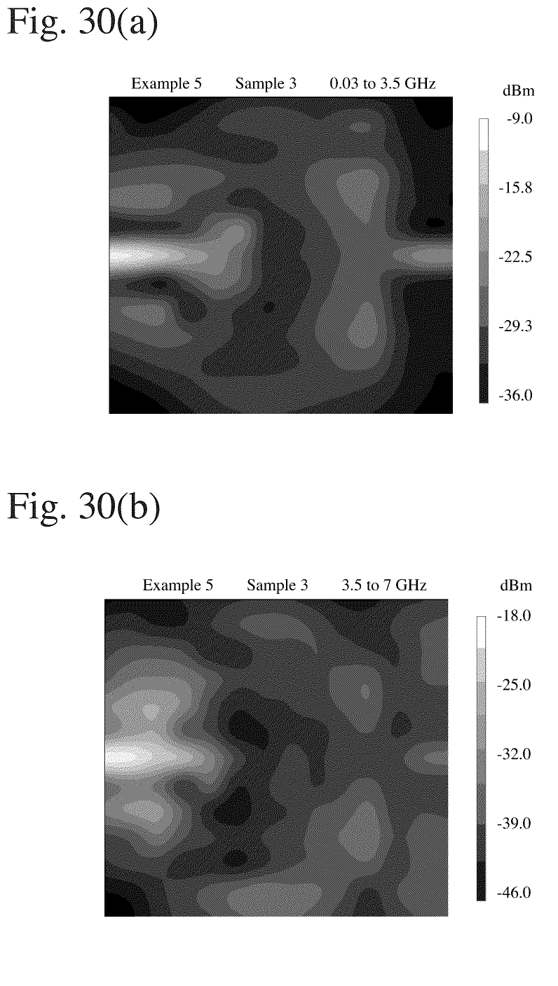

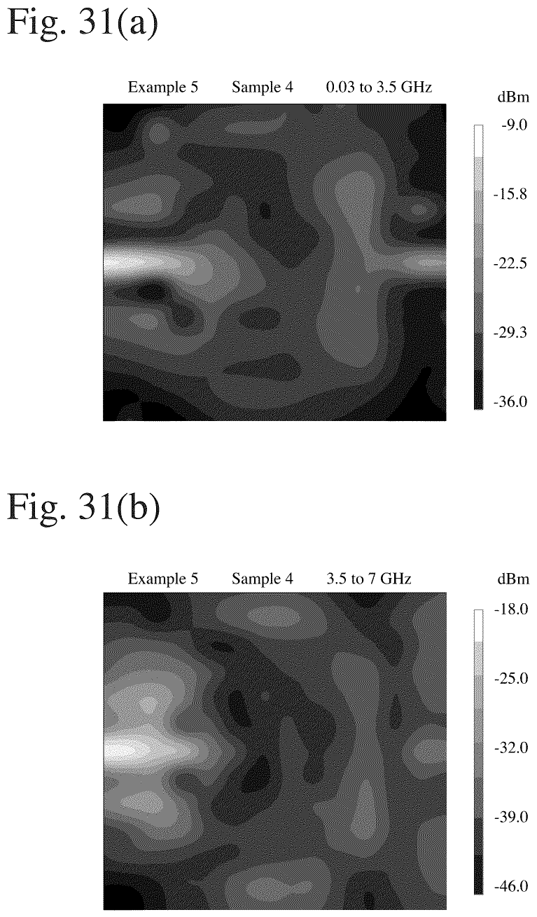

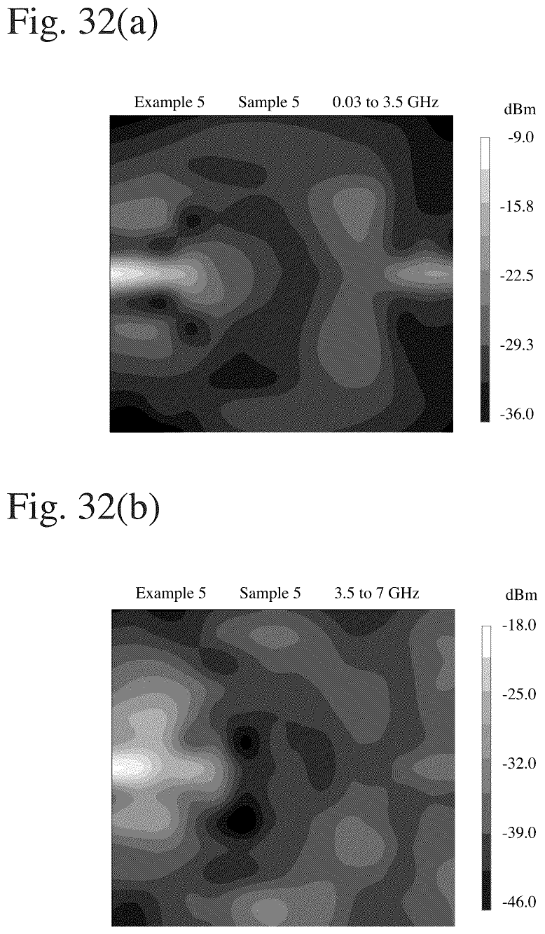

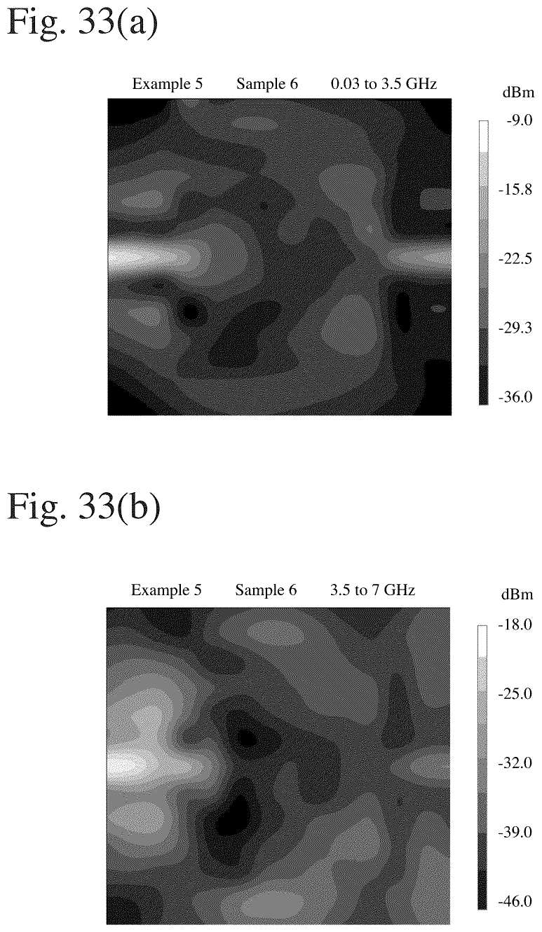

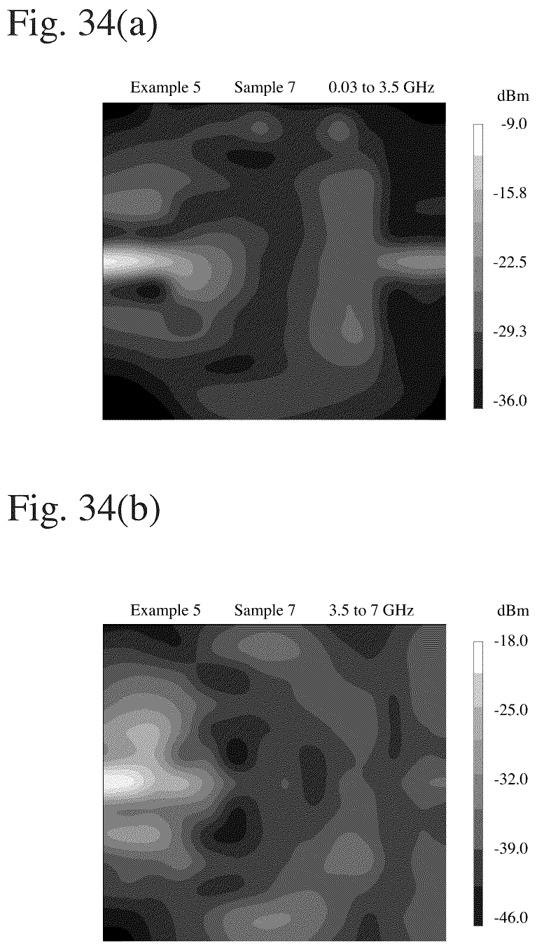

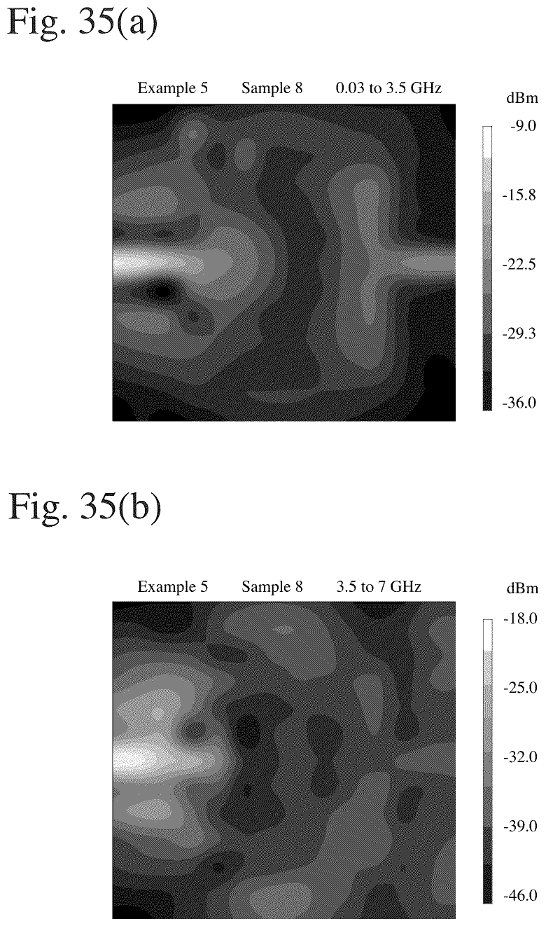

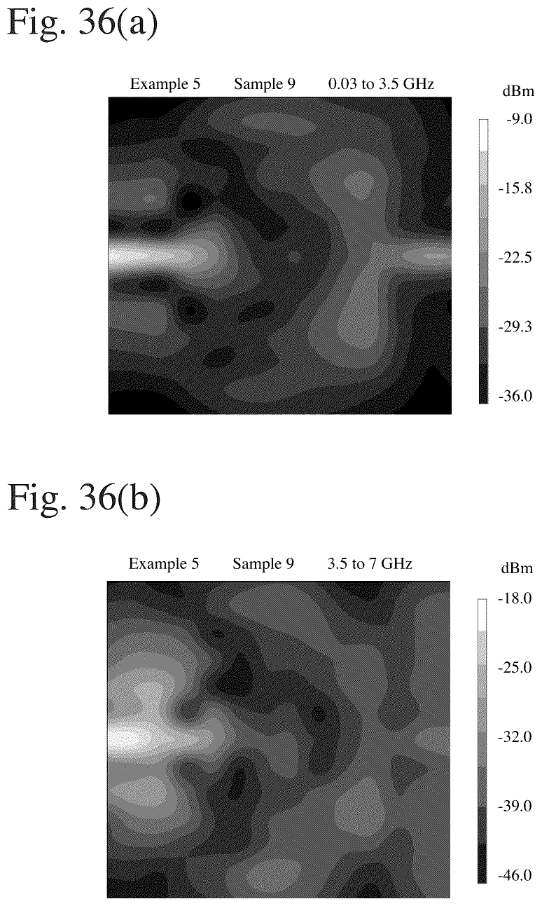

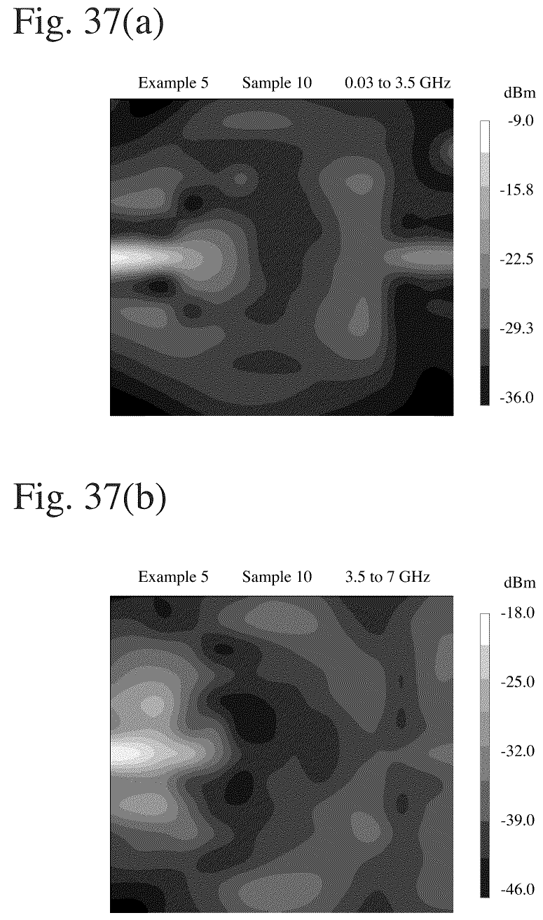

As is clear from FIGS. 28 to 37, any near-field electromagnetic wave absorber according to the present invention formed by adhering each electromagnetic-wave-absorbing film arbitrarily selected from the production lot having the degree M₁ of forming linear scratches to each electromagnetic-wave-absorbing film arbitrarily selected from the production lot having the degree W₁ of forming linear scratches leaked only small cumulative radiation noises. This confirms that the near-field electromagnetic wave absorber of the present invention can stably suppress radiation noises, with substantially no or small unevenness, in any combination of the degrees M₁ and W₁ of forming linear scratches, which provides electromagnetic-wave-absorbing films with the surface resistivities meeting the requirements of the present invention.

### Comparative Example 11

10 electromagnetic-wave-absorbing film pieces were arbitrarily cut out of a single roll (first roll) of the electromagnetic-wave-absorbing film produced in Reference Example 1, in which the degree of forming linear scratches was M₁. Also, 10 electromagnetic-wave-absorbing film pieces were arbitrarily cut out of another roll (second roll) of an electromagnetic-wave-absorbing film produced under the same conditions as in Reference Example 1, in which the degree of forming linear scratches was M₁. Each electromagnetic-wave-absorbing film piece in the first roll was arbitrarily combined with each electromagnetic-wave-absorbing film piece in the second roll, and adhered by a nonconductive adhesive with their linear-scratched thin aluminum films inside, to obtain 10 test pieces TP2 of the near-field electromagnetic wave absorber. Each of the test pieces TP2 was measured with respect to radiation noises in the same manner as in Example 5. FIGS. 38 to 47 show cumulative radiation noises in a range from 0.03 GHz to 3.5 GHz and those in a range from 3.5 GHz to 7 GHz, respectively.

As is clear from FIGS. 38-47, among near-field electromagnetic wave absorber samples obtained by adhering each electromagnetic-wave-absorbing film arbitrarily selected from one roll, in which the degree of forming linear scratches was M₁, to each electromagnetic-wave-absorbing film arbitrarily selected from another roll, in which the degree of forming linear scratches was also M₁, all samples except for Sample 8 suffered large cumulative radiation noises, and only Sample 8 exhibited good radiation noise absorbability. This confirms that when two electromagnetic-wave-absorbing films having the suitable degree M₁ of forming linear scratches in different rolls are arbitrarily combined, most of the resultant near-field electromagnetic wave absorbers fail to exhibit satisfactory radiation noise absorbability, though some of them may well suppress radiation noises.

Also, as is clear from Table 2, all of the near-field electromagnetic wave absorber of Comparative Example 7 obtained by combining two electromagnetic-wave-absorbing films of Reference Example 3 (the degree of forming linear scratches: W₁), the near-field electromagnetic wave absorber of Comparative Example 8 obtained by combining two electromagnetic-wave-absorbing films of Reference Example 4 (the degree of forming linear scratches: W₂), and the near-field electromagnetic wave absorber of Comparative Example 10 obtained by combining two electromagnetic-wave-absorbing films of Reference Example 5 (the degree of forming linear scratches: S₁) were insufficient in radiation noise absorbability. This confirms that if electromagnetic-wave-absorbing films having the same degree of forming linear scratches (surface resistivity) were combined, sufficient radiation noise absorbability would not be obtained, regardless of whether the degree of forming linear scratches (surface resistivity) is changed.

### DESCRIPTION OF REFERENCE NUMERALS

1: Near-field electromagnetic wave absorber.
100, 100a, 100b: Electromagnetic-wave-absorbing film.
10, 10a, 10b: Plastic film.
11, 11a, 11b: Thin metal film.
12, 12a, 12b, 12c, 12d: Linear scratches.
2a, 2b, 2c, 2d: Pattern roll.
3a, 3b, 3c, 3d, 3e: Push roll.
20: Adhesive layer.

What is claimed is:

1. A near-field electromagnetic wave absorber comprising at least one plastic film and two linearly-scratched thin metal films, each of said linearly-scratched thin metal films having large numbers of substantially parallel, intermittent, linear scratches with irregular widths and intervals in plural directions, one linearly-scratched thin metal film having a surface resistivity of 150-300Ω/square, and the other linearly-scratched thin metal film having a surface resistivity of 10-50Ω/square.

2. The near-field electromagnetic wave absorber according to claim 1, wherein a pair of plastic films each having a linearly-scratched thin metal film on one side are adhered to each other.

3. The near-field electromagnetic wave absorber according to claim 2, wherein both linearly-scratched thin metal films are adhered to each other.

4. The near-field electromagnetic wave absorber according to claim 1, wherein said near-field electromagnetic wave absorber is composed of one plastic film and two linearly-scratched thin metal films formed on both sides of said plastic film.

5. The near-field electromagnetic wave absorber according to claim 1, wherein both thin metal films are as thick as 20-100 nm.

6. The near-field electromagnetic wave absorber according to claim 1, wherein the linear scratches formed in both thin metal films are oriented in two directions with a crossing angle of 30-90°.

7. The near-field electromagnetic wave absorber according to claim 1, wherein one of said linearly-scratched thin metal films has a light transmittance of 2.5-3.5%, and the other has a light transmittance of 1-2.2%.

8. The near-field electromagnetic wave absorber according to claim 1, wherein both thin metal films are made of aluminum.

9. The near-field electromagnetic wave absorber according to claim 1, wherein one linearly-scratched thin metal film has a surface resistivity of 150-210Ω/square, and the other linearly-scratched thin metal film has surface resistivity of 10-50Ω/square.

10. The near-field electromagnetic wave absorber according to claim 1, wherein linear scratches formed in both thin metal films have widths in a range of 0.1-100 μm and 2-50 μm on average, and intervals in a range of 0.1-500 μm and 10-100 μm on average.
